(19) United States
(12) Patent Application Publication
(10) Pub. No.: US 2025/0158589 A1
(43) Pub. Date: May 15, 2025

(54) ACOUSTIC WAVE DEVICE INCLUDING ION IMPLANTED PIEZOELECTRIC LAYER

(71) Applicant: Skyworks Global Pte. Ltd., Singapore (SG)

(72) Inventors: Kwang Jae Shin, Yongin-si (KR); Stefan Bader, Fort Collins, CO (US); Alexandre Augusto Shirakawa, Cardiff by the Sea, CA (US); Martha Kennedy Small, Fort Collins, CO (US); Michael David Hill, Emmitsburg, MD (US)

(21) Appl. No.: 18/942,323

(22) Filed: Nov. 8, 2024

Related U.S. Application Data
(60) Provisional application No. 63/548,149, filed on Nov. 10, 2023.
(60) Provisional application No. 63/548,143, filed on Nov. 10, 2023.
(60) Provisional application No. 63/548,144, filed on Nov. 10, 2023.
(60) Provisional application No. 63/548,129, filed on Nov. 10, 2023.

(51) Int. Cl. H03H 9/02; H03H 3/04; H03H 9/17; H03H 9/56

(52) U.S. Cl. CPC H03H 9/02031; H03H 3/04; H03H 9/173; H03H 9/176; H03H 9/562; H03H 9/564; H03H 9/568; H03H 2003/0478

(57) ABSTRACT

The disclosed technology relates to an acoustic wave device including a piezoelectric layer with localized regions having atoms implanted therein, and an electrode over the piezoelectric layer, where the acoustic wave device is configured to generate an acoustic wave.

### CROSS-REFERENCE TO RELATED APPLICATION

This application claims the benefit of U.S. Provisional Application No. 63/548,149, entitled “METHOD OF FABRICATING ACOUSTIC WAVE DEVICE INCLUDING ION IMPLANTED PIEZOELECTRIC LAYER,” filed Nov. 10, 2023, U.S. Provisional Application No. 63/548,143, entitled “ACOUSTIC WAVE DEVICE INCLUDING ION IMPLANTED PIEZOELECTRIC LAYER,” filed Nov. 10, 2023, U.S. Provisional Application No. 63/548,144, entitled “ACOUSTIC WAVE DEVICE WITH ION IMPLANTED TEMPERATURE COMPENSATION LAYER,” filed Nov. 10, 2023, and U.S. Provisional Application No. 63/548,129, entitled “ACOUSTIC WAVE DEVICE WITH ION IMPLANTED MASS LOADED LAYER,” filed Nov. 10, 2023. The content of each of the above applications is hereby incorporated by reference in its entirety.

### BACKGROUND

### Technical Field

The disclosed technology relates to acoustic wave devices. Embodiments of this disclosure relate to acoustic wave devices with a piezoelectric layer.

### Description of Related Technology

An acoustic wave filter can include a plurality of acoustic wave resonators arranged to filter a radio frequency signal. Example acoustic wave resonators include surface acoustic wave (SAW) resonators and bulk acoustic wave (BAW) resonators. A SAW resonator can include an interdigital transductor electrode on a piezoelectric substrate. The SAW resonator can generate a surface acoustic wave on a surface of the piezoelectric layer on which the interdigital transductor electrode is disposed. In BAW resonators, acoustic waves propagate in the bulk of a piezoelectric layer. Example BAW resonators include film bulk acoustic wave resonators (FBARs) and BAW solidly mounted resonators (SMRs).

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave device can include piezoelectric layer. Properties of the piezoelectric layer can impact performance of the acoustic wave device. For example, in a BAW device, a material of the piezoelectric layer and thickness of the piezoelectric layer can impact a resonant frequency of the BAW device.

Temperature compensation can be desirable in acoustic wave devices. An acoustic wave device can include a temperature compensation layer to bring a temperature coefficient of frequency (TCF) closer to zero. For example, a BAW device can include a temperature compensation layer between a piezoelectric layer and an electrode.

Acoustic wave devices can include one or more mass loading layers. For example, BAW devices in a filter can have different resonant frequencies as a result of different mass loading.

### SUMMARY

In a first aspect, a method of fabricating an acoustic wave device includes providing a piezoelectric layer for forming the acoustic wave device, selectively implanting ions into localized regions of the piezoelectric layer, and further processing to configure the acoustic wave device to generate an acoustic wave.

In a second aspect, a method of fabricating one or more acoustic wave devices comprises providing a plurality of piezoelectric layers laterally arranged over a common substrate, implanting different ones of the piezoelectric layers differently, and further processing to form the one or more acoustic wave devices configured to generate an acoustic wave.

In a third aspect, a method of fabricating one or more acoustic wave devices comprises providing a piezoelectric layer over a substrate, blanket-implanting ions into the piezoelectric layer, and patterning the piezoelectric layer and further processing to form the one or more acoustic wave devices configured to generate an acoustic wave.

In a fourth aspect, an acoustic wave device comprises a piezoelectric layer comprising localized regions having atoms implanted therein, and an electrode over the piezoelectric layer, where the acoustic wave device is configured to generate an acoustic wave.

In a fifth aspect, an acoustic device comprises a plurality of piezoelectric layers laterally arranged over a common substrate, where different ones of the piezoelectric layers are implanted differently, and electrodes formed over the piezoelectric layers and configured to generate an acoustic wave.

In a sixth aspect, an acoustic wave device with temperature compensation comprises a piezoelectric layer, an electrode and a temperature compensation layer including an implanted species therein from ion implantation, where the acoustic wave device is configured to generate an acoustic wave.

In a seventh aspect, a method of manufacturing an acoustic wave device with temperature compensation comprises providing an acoustic wave device structure that includes a temperature compensation layer, and performing ion implantation to implant a dopant in the temperature compensation layer.

In an eighth aspect, an acoustic wave filter comprises the acoustic wave device of the sixth aspect and a plurality of additional acoustic wave devices, where the acoustic wave filter is configured to filter a radio frequency signal.

In a ninth aspect, a radio frequency module comprises an acoustic wave filter of the eighth aspect, and a radio frequency circuit element coupled to the acoustic wave filter, where the acoustic wave filter and the radio frequency circuit element are enclosed within a common package.

In a tenth aspect, a wireless communication device comprises the acoustic wave filter of the eighth aspect, and further comprises an antenna operatively coupled to the acoustic wave filter, a radio frequency amplifier operatively coupled to the acoustic wave filter and configured to amplify a radio frequency signal, and a transceiver in communication with the radio frequency amplifier.

In an eleventh aspect, a method of filtering a radio frequency signal comprises receiving a radio frequency signal at a port of the acoustic wave filter of the eight aspect, and further comprises filtering the radio frequency signal with the acoustic wave filter.

In a twelfth aspect, an acoustic wave component with mass loaded bulk acoustic wave devices comprises a first bulk acoustic wave device having a first resonant frequency, and a second bulk acoustic wave device having a second resonant frequency, where the second bulk wave device includes a mass loaded layer having an implanted species therein from ion implantation, and where the implanted species of the mass loaded layer contributes to a difference between the first resonant frequency and the second resonant frequency.

In a thirteenth aspect, a method of manufacturing bulk acoustic wave devices with mass loading using ion implantation comprises providing a bulk acoustic wave device structure that includes a first layer in a first area corresponding to a first bulk acoustic wave device and a second layer in a second area corresponding to a second bulk acoustic wave device, and performing ion implantation to implant a dopant into the first layer such that the first layer has a greater mass than the second layer.

In a fourteenth aspect, an acoustic wave filter comprises an acoustic wave device of the twelfth aspect, and a plurality of additional acoustic wave devices, the acoustic wave filter configured to filter a radio frequency signal.

In a fifteenth aspect, a radio frequency module comprises an acoustic wave filter of the fourteenth aspect, and a radio frequency circuit element coupled to the acoustic wave filter, where the acoustic wave filter and the radio frequency circuit element is enclosed within a common package.

In a sixteenth aspect, a wireless communication device comprises an acoustic wave filter of the fourteenth aspect, further comprising an antenna operatively coupled to the acoustic wave filter, a radio frequency amplifier operatively coupled to the acoustic wave filter and configured to amplify a radio frequency signal, and a transceiver in communication with the radio frequency amplifier.

In a seventeenth aspect, a method of filtering a radio frequency signal comprises receiving a radio frequency signal at a port of an acoustic wave filter of the fourteenth aspect, and further comprising filtering the radio frequency signal with the acoustic wave filter.

### BRIEF DESCRIPTION OF THE DRAWINGS

Embodiments of this disclosure will now be described, by way of non-limiting example, with reference to the accompanying drawings.

FIG. 1A is a cross sectional diagram of a bulk acoustic wave (BAW) device according to an embodiment. FIG. 1B is an example plan view of the BAW device of FIG. 1A.

FIG. 2A is a top view of an interdigital transducer (IDT) electrode of a surface acoustic wave (SAW) device according to an embodiment. FIG. 2B is a cross-sectional view of the SAW device of FIG. 2A.

FIG. 3 is a cross-sectional view of a temperature compensated SAW (TCSAW) device according to an embodiment.

FIG. 4 is a cross-sectional view of a multilayer piezoelectric substrate (MPS) SAW device according to an embodiment.

FIG. 5A is a cross sectional diagram of a bulk acoustic wave (BAW) device having a locally modified piezoelectric material property, according to an embodiment.

FIG. 5B illustrates a flow diagram of a method of fabricating a bulk acoustic wave (BAW) device having a locally modified piezoelectric material property, according to an embodiment.

FIG. 6A is a cross sectional diagram of an intermediate device structure illustrating a method of fabricating an acoustic wave device having a plurality of acoustic wave resonators, according to an embodiment.

FIG. 6B is a cross sectional diagram of an intermediate device structure illustrating a method of fabricating an acoustic wave device having a plurality of acoustic wave resonators, according to an embodiment.

FIG. 6C illustrates a flow diagram of a method of fabricating an acoustic wave device having a plurality of acoustic wave resonators, according to an embodiment.

FIG. 7A illustrates adjustment of within-wafer concentration of a piezoelectric layer, according to an embodiment.

FIG. 7B illustrates a flow diagram of a method of adjusting within-wafer concentration of a piezoelectric layer, according to an embodiment.

FIG. 8 is a flow diagram of a method of manufacturing an acoustic wave device with temperature compensation.

FIG. 9 is a cross sectional diagram of a BAW device according to an embodiment.

FIG. 10 is a cross-sectional diagram of a BAW device according to an embodiment.

FIG. 11 is a cross-sectional view of a portion of a temperature compensated BAW (TCBAW) device according to an embodiment.

FIG. 12 is a cross-sectional view of a portion of a TCBAW device according to an embodiment.

FIG. 13 is a cross-sectional view of the TCSAW device that includes a temperature compensation layer with an implanted species,

FIG. 14 is a cross-sectional view of an MPS SAW device according to an embodiment.

FIG. 15 is a cross-sectional view of an MPS SAW device according to another embodiment.

FIG. 16 is a cross-sectional view of an MPS SAW device according to another embodiment.

FIG. 17 is a flow diagram of a method of manufacturing bulk acoustic wave devices with mass loading.

FIG. 18 is a top plan view schematically illustrating a BAW die that includes BAW resonators with different mass loads.

FIG. 19 is a top plan view schematically illustrating a BAW die that includes BAW resonators with different mass loads.

FIG. 20 is a flow diagram for a process of manufacturing BAW resonators.

FIG. 21 is a schematic diagram of a ladder filter that includes a plurality of BAW resonators.

FIG. 22 is an example schematic cross-sectional diagram showing material stacks of example BAW resonators of the ladder filter of FIG. 21 with different ion implanted mass load doses.

FIG. 23A is a schematic diagram of a ladder filter that includes an acoustic wave resonator according to an embodiment.

FIG. 23B is schematic diagram of an acoustic wave filter.

FIGS. 24A, 24B, 24C, and 24D are schematic diagrams of multiplexers that includes an acoustic wave resonator according to an embodiment.

FIGS. 25A, 25B, and 25C are schematic block diagrams of modules that include a filter with an acoustic wave device according to an embodiment.

FIG. 26 is a schematic block diagram of a wireless communication device that includes a filter with an acoustic wave device according to an embodiment.

FIG. 27 is a schematic diagram of one example of a communication network.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

Aspects of this disclosure relate to an acoustic wave device having a piezoelectric layer including localized regions having atoms implanted therein, and methods of fabricating the acoustic wave device. Ion implantation can be employed to modify a piezoelectric material property at the localized regions of the piezoelectric layer of a given device. The acoustic wave device can be fabricated by providing a piezoelectric layer for forming the acoustic wave device and selectively implanting ions into localized regions of the piezoelectric layer. Selective implanting can be performed using a masking layer such as a photoresist. The material property can include the material-coupling coefficient, and lowering the material-coupling coefficient at edge regions of an active area of the acoustic wave resonator can reduce laterally leaking waves. Example elements that can lower the material-coupling coefficient include noble gas, oxygen, hydrocarbon, B, Si and C. The piezoelectric layer including localized regions can be further processed to configure the acoustic wave device to generate an acoustic wave.

Aspects of this disclosure relate to one or more acoustic wave devices including a plurality of piezoelectric layers laterally arranged over a common substrate, where different ones of the piezoelectric layers are implanted differently. Ion implantation can be employed to modify a piezoelectric material property the different ones of the piezoelectric layers differently. The acoustic wave can be fabricated by providing a plurality of piezoelectric layers over a common substrate, and implanting different ones of the piezoelectric layers differently. Different implantations can be performed using a masking layer such as a photoresist. The material property can include the material-coupling coefficient. Example elements that can lower the material-coupling coefficient include noble gas, oxygen, hydrocarbon, B, Si and C. Example elements that can increase the material-coupling coefficient include Cr, Sc, Y, Mg, Zr and Hf. The plurality of piezoelectric layers can be patterned and further processed to form the one or more acoustic wave devices configured to generate an acoustic wave.

Aspects of this disclosure relate to a method of fabricating one or more acoustic wave devices by modifying a piezoelectric layer at the wafer level. Ion implantation can be employed to modify a piezoelectric material property at the wafer level. A method of fabricating one or more acoustic wave devices includes providing a piezoelectric layer over a substrate and blanket-implanting ions into the piezoelectric layer. Example piezoelectric material properties that can be modified include material-coupling coefficient. Example elements that can lower the material-coupling coefficient include noble gas, oxygen, hydrocarbon, B, Si and C. Example elements that can increase the material-coupling coefficient include Cr, Sc, Y, Mg, Zr and Hf. The piezoelectric layer can be patterned and further processed to form the one or more acoustic wave devices configured to generate an acoustic wave.

Aspects of this disclosure relate to ion implantation in a temperature compensation layer of an acoustic wave device. With ion implantation, low and precise doping levels can be achieved in a temperature compensation layer. Ion implantation can increase temperature compensation of a temperature compensation layer. An ion implanted temperature compensation layer can be relatively thin and achieve desirable temperature compensation. An example temperature compensation layer can be a silicon dioxide layer. Example dopants that can be implanted in the temperature compensation layer include, but are not limited to, boron and phosphorous. In certain embodiments, the acoustic wave device can be a BAW device. The BAW device can include a temperature compensation layer between a piezoelectric layer and an electrode in certain applications. The BAW device can include a temperature compensation layer embedded in an electrode in some applications.

Aspects of this disclosure relate to ion implantation in a layer of a BAW device. Ion implantation can be used in manufacturing BAW devices with different resonant frequencies. The implanted species can vary the mass loading and consequently the resonant frequency between different BAW devices. Ion implantation can be performed on relatively thin layers. An electrode of a BAW device can include an ion implanted mass loaded layer, for example. One or more other layers of a BAW device can alternatively or additionally be ion implanted to adjust mass loading. Relatively heavy implanted species can be implanted for mass loading, such as, but not limited to, one or more of iridium, osmium, platinum, chromium, tungsten, ruthenium, or molybdenum. An acoustic wave filter can include two BAW devices with different resonant frequencies, and ion implantation can contribute to the difference in resonant frequency between the two BAW devices.

### Ion Beam Enhanced Acoustic Wave Devices

Various properties of acoustic wave devices can be improved by introducing impurities such as dopants to portions of the acoustic wave devices. Such impurities can be introduced, e.g., during deposition of a layer. For example, by including a dopant in a target and co-sputtering, e.g., reactively co-sputtering with a base material in the target, a layer formed of the base material that is uniformly doped with the dopant may be formed. Similarly, a base material may be doped in evaporation processes such as molecular beam epitaxy by co-evaporating a base material as well as a dopant and co-depositing on a substrate. While such co-sputtering or co-evaporation processes may be employed to uniformly dope the resulting thin film or vary the composition of the thin film in the layer growth direction, such techniques are limited in their ability to vary the composition in a lateral direction parallel to the surface of the thin film, or to locally vary the composition of the thin film. Thus, there is a need for versatile modification techniques for modifying or locally modifying the composition and/or structure of thin films in a lateral direction.

The inventors have discovered that ion implantation may be employed for modifying or locally modifying the structure and/or composition of a thin film layer in a lateral direction parallel to the surface of the thin film. Ion implantation is a low-temperature technique for the introduction of impurities (e.g., dopants) and offers more flexibility than other techniques such as co-sputtering, co-evaporation or diffusion. Among other characteristics, ion implantation can be performed after formation of a thin film, thereby providing a degree of freedom for modification of the properties of the thin film. In ion implantation, dopant atoms are volatilized, ionized, accelerated, separated by the mass-to-charge ratios, and directed at a target, which can be a thin film formed on a substrate. Thus accelerated ions have precise energy and high purity. The ions enter the crystal lattice, collide with the host atoms, lose energy, and finally come to rest at some depth within the target. The average penetration depth is determined by the mass and ionization of the dopant, substrate materials, and acceleration energy. Ion implantation energies range from several hundred to several million electron volts, and the resulting projected range can be controlled from <10 nm to 10 μm or even greater. The average depth of the implanted ions is called the projected range (Rₚ), and at the distribution of the implanted ions about that depth can be approximated as Gaussian with a standard deviation σp (or ΔRₚ). For example, without being bound by any theory, it will be appreciated that at least portions of the concentration (n(x)) distribution curve of implanted ions as a function of the depth x can be approximated by a Gaussian distribution expressed as

$$n ( x ) = {n}_{o} exp \{ - \frac{{( x - {R}_{p} )}^{2}}{2 {σ}_{p}^{2}} \} ,$$

where nₒ represents the peak concentration, Rp is the projected range and sₚ is the standard deviation. In part due to the statistical distribution of the implanted ions about the projected range within the target, e.g., in a surface normal direction of a thin film of an acoustic wave device, an implanted profile has a characteristic statistical tail distribution towards opposite ends of the implantation profile.

A further advantage of ion implantation is that the concentration of the implanted ions can be precisely controlled by measuring the ion current. Furthermore, because of the physical nature of ion implantation, elements that can be implanted depend relatively little on the target. That is, regardless of the chemical compatibility between the dopant and the target, the dopant can be introduced into the target.

A further advantage of ion implantation is that, because the ions are implanted after a target material such as a thin film is formed, the affected areas can be spatially selectively controlled. For example, while in-situ doping during deposition of a thin film can affect the composition of the entire film, ion implantation can be selectively performed by blocking off areas of the thin film where the dopant is not to be implanted into, e.g., using a photoresist or other masking means.

By taking advantage of these and other characteristics of ion implantation, according to various embodiments of acoustic wave devices disclosed herein, one or more regions or layers of the acoustic wave devices maybe modified using ion beams.

Ion beam modification as disclosed herein can be implemented in acoustic wave devices. For example, ion beam modification as disclosed herein can be implemented in BAW devices, such as film bulk acoustic wave resonators (FBARs) and BAW solidly mounted resonators (SMRs). As another example, ion beam modification disclosed herein can be implemented in surface acoustic wave (SAW) devices, such as non-temperature compensated SAW devices, temperature compensated SAW (TC SAW) devices, and multilayer piezoelectric substrate (MPS) SAW devices. As one more example, ion beam modification as disclosed herein can be implemented in Lamb wave elements, such as Lamb wave resonators and Lamb wave delay lines. As one more example, ion beam modifications disclosed herein can be implemented in boundary wave resonators. Example acoustic wave devices will now be discussed. Any suitable principles and advantages disclosed herein can be implemented in any of these example acoustic wave devices.

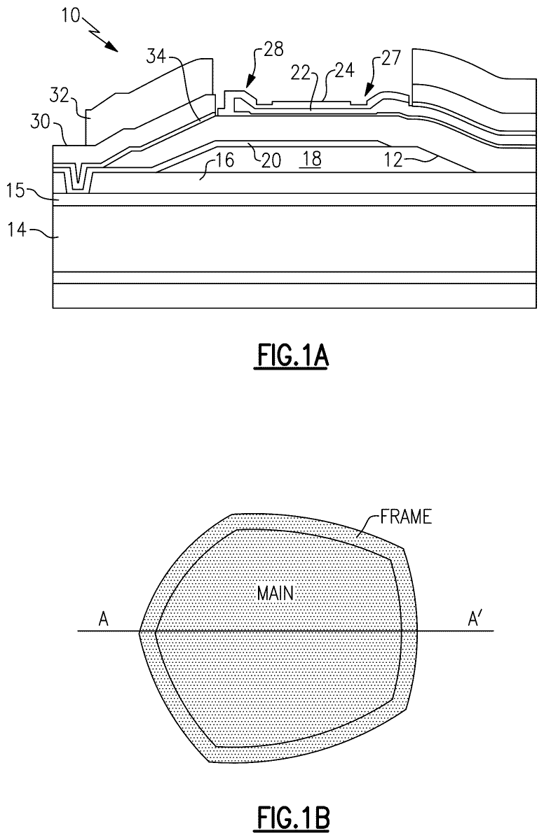

FIG. 1A is a cross sectional diagram of a BAW device 10 according to an embodiment. The BAW devices 10 includes a piezoelectric layer 12. The piezoelectric layers disclosed herein can be implemented in BAW devices. In BAW devices, a piezoelectric layer having a higher acoustic velocity can contribute to a higher resonant frequency for a given piezoelectric layer thickness. A BAW device with a piezoelectric layer in accordance with any suitable principles and advantages disclosed herein can have a resonant frequency of at least 6 GHz. A BAW device with a piezoelectric layer in accordance with any suitable principles and advantages disclosed herein can have a resonant frequency in a range from 6 GHz to 15 GHz. In some of these instances, a BAW device can have a resonant frequency in a range from 6 GHz to 10 GHz. A BAW device with a thicker piezoelectric layer with a higher acoustic velocity can have a same resonant frequency as another BAW device with a thinner piezoelectric layer and a lower acoustic velocity. BAW resonators, such as FBARs and BAW SMRs, can include piezoelectric layers in accordance with any suitable principles and advantages disclosed herein. An example of such a BAW resonator will be discussed with reference to FIG. 1A.

The piezoelectric layer 12 can be formed of a suitable material including aluminum nitride (AlN), zinc oxide (ZnO) and lead zirconium titanate (PZT). The piezoelectric material can be poly-crystalline, a single crystal. The piezoelectric material can be doped or undoped. For example, an AlN-based piezoelectric layer can be doped with any suitable dopant, such as chromium (Cr), scandium (Sc), chromium (Cr), magnesium (Mg), sulfur(S), yttrium (Y), silicon (Si), germanium (Ge), oxygen (O), hafnium (Hf), zirconium (Zr), titanium (Ti), or the like. Doping the piezoelectric layer 12 can adjust the resonant frequency. Doping the first piezoelectric layer 12 can increase the coupling coefficient kₜ² of the BAW device 10. Doping to increase the coupling coefficient kₜ² can be advantageous at higher frequencies where the coupling coefficient kₜ² can be degraded.

In certain applications, two or more piezoelectric layers in accordance with any suitable principles and advantages disclosed herein can be stacked with each other between electrodes of a BAW device. The stacked piezoelectric layers can have c-axes oriented in opposite directions and excite an overtone mode as a main mode of a BAW resonator.

As illustrated in FIG. 1A, the BAW device 10 includes a support substrate 14, a trap rich layer 15, a first passivation layer 16, an air cavity 18, a first electrode 20, the piezoelectric layer 12, a second electrode 22, a temperature compensation layer positioned between the piezoelectric layer 12 and the second electrode, and a second passivation layer 24. The BAW device 10 also includes a recessed frame structure 27 and a raised frame structure 28.

The support substrate 14 can be a semiconductor substrate. The support substrate 14 can be a silicon substrate. The support substrate 14 can be any other suitable support substrate. The trap rich layer 15 can be a polysilicon layer, an amorphous silicon layer, or the like. The trap rich layer 15 is positioned between the support substrate 14 and the first passivation layer 16. The first passivation layer 16 can be referred to as a lower passivation layer. The first passivation layer 16 can be referred to as a bottom oxide layer when the lower passivation layer includes an oxide. The first passivation layer 16 can be a silicon dioxide layer or any other suitable passivation layer, such as aluminum oxide, silicon carbide, aluminum nitride, silicon nitride, silicon oxynitride, or the like.

The air cavity 18 is an example of an acoustic reflector. As illustrated, the air cavity 18 is located above the support substrate 14. The air cavity 18 is positioned between the support substrate 14 and the first electrode 20. In some applications, an air cavity can be etched into a support substrate. In certain applications, a solid acoustic mirror with alternating high acoustic impedance and low acoustic impedance layers can be included in place of an air cavity. A BAW device with an air cavity can be referred to as an FBAR. A BAW device with a solid acoustic mirror can be referred to as a BAW SMR.

The first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), Ir/Pt, or any suitable alloy and/or combination thereof. Similarly, the second electrode 22 can have a relatively high acoustic impedance. The second electrode 22 can include Mo, W, Ru, Cr, Ir, Pt, Ir/Pt, or any suitable alloy and/or combination thereof. The second electrode 22 can be formed of the same material as the first electrode 20 in certain instances. The second electrode 22 can be referred to as an upper electrode. The thickness of the first electrode 20 can be approximately the same as the thickness of the second electrode 22 in a main acoustically active region of the BAW device 10. The first electrode 20 and the second electrode 22 can be the only electrodes of the BAW device 10.

The second passivation layer 24 can be referred to as an upper passivation layer. The second passivation layer 24 can be a silicon dioxide layer or any other suitable passivation layer, such as aluminum oxide, silicon carbide, aluminum nitride, silicon nitride, silicon oxynitride, or the like. The second passivation layer 24 can be the same material as the first passivation layer 15 in certain instances. The second passivation layer 24 can have different thicknesses in different regions of the BAW device 10. Part of the second passivation layer 24 can form at least part of the recessed frame structure 27 and/or the raised frame structure 28.

An active region or active domain of the BAW device 10 can be defined by a portion of the piezoelectric layer 12 that overlaps an acoustic reflector, such as the air cavity 18, and is between the first electrode 20 and the second electrode 22. The active region can correspond to where voltage is applied on opposing sides of the piezoelectric layer 12 over the acoustic reflector. The active region can be the acoustically active region of the BAW device 10. The BAW device 10 also includes a recessed frame region with the recessed frame structure 27 in the active region and a raised frame region with the raised frame structure 28 in the active region. The main acoustically active region can provide a main mode of the BAW device 10. The main acoustically active region can be the central part of the active region that is free from frame structures, such as the recessed frame structure 27 and the raised frame structure 28.

While the BAW device 10 includes the recessed frame structure 27 and the raised frame structure 28, other frame structures can alternatively or additionally be implemented. For example, a raised frame structure with multiple layers including a layer between an electrode of a BAW device and a piezoelectric layer can be implemented. As another example, a floating raised frame structure can be implemented. As one more example, a raised frame structure can be implemented without a recessed frame structure.

One or more conductive layers 30 and 32 can connect an electrode of the BAW device 10 to one or more other BAW devices, one or more integrated passive devices, one or more other circuit elements, one or more signal ports, the like, or any suitable combination thereof. An adhesion layer 34 can be positioned between the conductive layer 30 and an underlying layer to increase adhesion between the layers. The adhesion layer 34 can be a titanium layer, for example.

FIG. 1B is an example plan view of the BAW device 10 of FIG. 1A. The cross-sectional view of FIG. 1A can be along the line from A to A′ in FIG. 1B. In FIG. 1B, the frame region FRAME and the main acoustically active region MAIN are shown. As illustrated, the main acoustically active region MAIN can correspond be the majority of the area of the BAW device 10. The frame region FRAME includes the recessed frame structure 17 and the raised frame structure 18 of the BAW device 10 of FIG. 1A. FIG. 1B illustrates the BAW device 10 with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

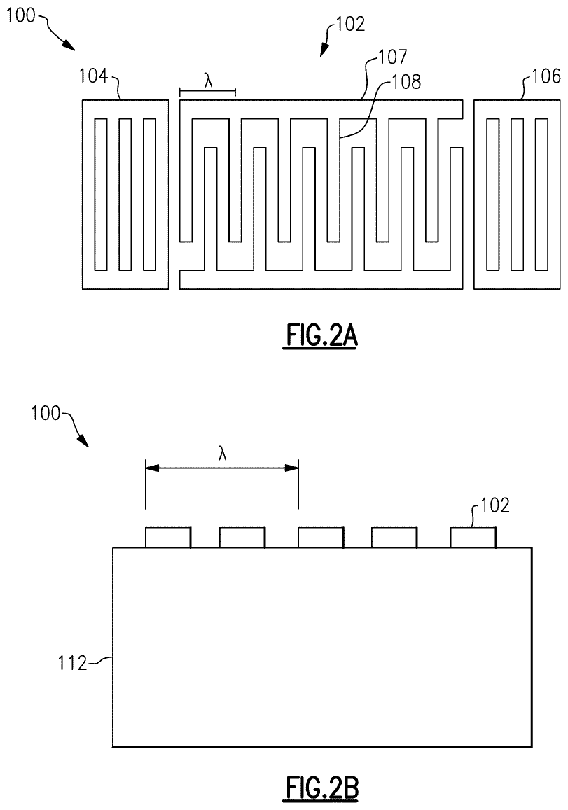

The piezoelectric layers disclosed herein can be implemented in SAW devices. A saw device can be a SAW resonator, a multi-mode SAW filter with longitudinally coupled interdigital transducer electrodes positioned between acoustic reflectors, a SAW delay line, or the like. In SAW devices, a piezoelectric layer having a higher acoustic velocity can allow interdigital transducer (IDT) electrode pitch to be greater than for a lower acoustic velocity piezoelectric layer SAW device with the same resonant frequency. A high acoustic velocity piezoelectric layer can make SAW devices easier to manufacture with larger pitches. Alternatively, a SAW device with a higher acoustic velocity piezoelectric layer can have a higher resonant frequency than as another SAW device with a lower acoustic velocity material and the same IDT pitch. TCSAW resonators, non-temperature compensated SAW resonators, and/or MPS SAW resonators can include piezoelectric layers in accordance with any suitable principles and advantages disclosed herein. Examples of such SAW device will be discussed with reference to FIGS. 2A to 4.

FIG. 2A is a top view of an interdigital transducer (IDT) electrode 102 of a SAW device 100. FIG. 2B is a cross-sectional view of the SAW device 100 of FIG. 2A. The IDT electrode 102 is positioned between a first acoustic reflector 104 and a second acoustic reflector 106. The acoustic reflectors 104 and 106 are separated from the IDT electrode 102 by respective gaps. The IDT electrode 102 includes the bus bar 107 and IDT fingers 108 extending from the bus bar 107. The IDT fingers 108 have a pitch of λ. The SAW device 100 can include any suitable number of IDT fingers 108. The pitch λ of the IDT fingers 108 corresponds to wavelength of a surface acoustic wave generated by the SAW device 100.

The SAW device 100 illustrated in FIG. 2B includes a piezoelectric layer 112 and an IDT electrode 102 on the piezoelectric layer 112. The piezoelectric layer 112 can be implemented in accordance with any suitable principles and advantages disclosed herein. The IDT electrode 102 can include any suitable material for an electrode, such as tungsten, aluminum, molybdenum, the like, or any suitable combination or alloy thereof. In some instances, the IDT electrode can include two or more metal layers. The SAW device 100 can included in a filter in accordance with any suitable principles and advantages disclosed herein.

FIG. 3 is a cross-sectional view of a TCSAW device 120. The illustrated TCSAW device 120 includes a piezoelectric layer 112, an IDT electrode 102 on the piezoelectric layer 112, and a temperature compensation layer 122 over the IDT electrode 102. The TCSAW device 120 is like the SAW device 100, except that the TCSAW device 120 includes a temperature compensation layer 122 over the IDT electrode 102. The piezoelectric layer 112 of the TCSAW device 120 can be implemented in accordance with any suitable principles and advantages disclosed herein.

The temperature compensation layer 122 can bring the temperature coefficient of frequency (TCF) of the TCSAW device 120 closer to zero relative to a similar SAW device without the temperature compensation layer 122. The temperature compensation layer 122 can have a positive TCF. This can compensate for the piezoelectric layer 112 having a negative TCF. The temperature compensation layer 122 can be a silicon dioxide (SiO₂) layer. The temperature compensation layer 122 can include any other suitable temperature compensating material including without limitation a tellurium dioxide (TeO₂) layer or a silicon oxyfluoride (SiOF layer). The temperature compensation layer 122 can include any suitable combination of SiO₂, TeO₂, and/or SiOF.

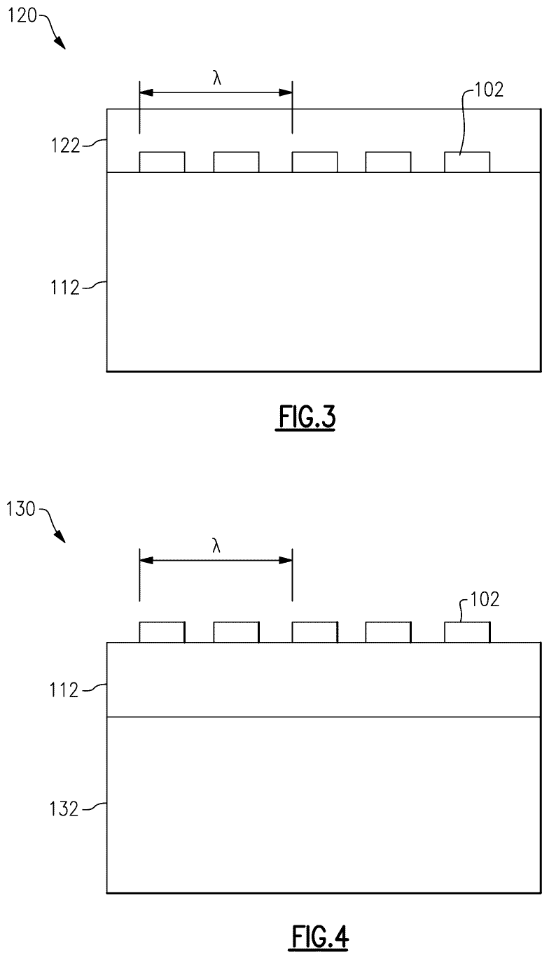

FIG. 4 is a cross-sectional view of a multilayer piezoelectric substrate (MPS) SAW device 130. The illustrated MPS SAW device 130 includes a multilayer piezoelectric substrate including a piezoelectric layer 112 and a support substrate 132. The MPS SAW device 130 also includes an IDT electrode 102 on the piezoelectric layer 112. The MPS SAW device 130 is like the SAW device 100, except that the MPS SAW device 130 includes the support substrate 132. In certain applications, the piezoelectric layer 112 can be thinner in the MPS SAW device 130 compared to in the SAW device 100. For example, the piezoelectric layer 112 can have a thickness of less than 2 in the MPS SAW device 130, in which λ is a wavelength of a surface acoustic wave generated by the MPS SAW device 130. In some other instances, the piezoelectric layer 112 can have a thickness on the order of 10s of λ, in which λ is a wavelength of a surface acoustic wave generated by the MPS SAW device 130. The piezoelectric layer 112 of the MPS SAW device 130 can be implemented in accordance with any suitable principles and advantages disclosed herein.

The support substrate 132 can be a silicon substrate, a quartz substrate, a sapphire substrate, a polycrystalline spinel substrate, or any other suitable carrier substrate. As one example, the MPS SAW device 130 can include a support substrate 132 that is silicon.

In some instances (not illustrated), one or more additional layers can be included in the multilayer piezoelectric substrate of an MPS SAW device. Non-limiting examples of a layer of the one or more additional layers include a silicon dioxide layer, a silicon nitride layer, an aluminum nitride layer, an adhesion layer, a dispersion adjustment layer, and a thermal dissipation layer. As an illustrative example, a multilayer piezoelectric substrate can include a piezoelectric layer over a silicon dioxide layer over an aluminum nitride layer over a silicon layer. As one more illustrative example, a multilayer piezoelectric substrate can include a piezoelectric layer over a silicon dioxide layer over a high impedance layer, in which the high impedance layer has a higher acoustic impedance than the piezoelectric. In some instances (not illustrated), a temperature compensation layer can be included over an IDT electrode of an MPS SAW device.

Acoustic Wave Device with Locally Ion-Implanted Piezoelectric Layer

As discussed above, various acoustic wave devices disclosed herein can have a piezoelectric layer which can have an altered or enhanced material property, e.g., by modifying the composition of the layer. For example, a material property of the piezoelectric layer can be tuned during deposition by doping to enhance, for example, the material-coupling coefficient. However, as discussed above, in-situ doping during deposition can affect the entire area of the piezoelectric layer that is being deposited on the substrate. However, in some circumstances, it may be desirable to locally modify the piezoelectric layer in one or more lateral directions without affecting the rest of the piezoelectric layer. For example, in some implementations, it may be desirable to locally increase or decrease the material-coupling coefficient (kₜ²) to enhance the overall performance of the acoustic wave device.

Accordingly, an acoustic wave device according to embodiments include a piezoelectric layer comprising localized regions having atoms implanted therein. The acoustic wave device additionally includes an electrode over the piezoelectric layer, the acoustic wave device configured to generate an acoustic wave.

The localized regions have a locally modified piezoelectric material property. The locally modified piezoelectric material property can include, among other things, piezoelectric constants, piezoelectric coefficients, the dielectric constant, piezoelectric coupling coefficients, elastic modulus, thermal expansion coefficient, acoustic velocity and loss angle tangent, to name a few.

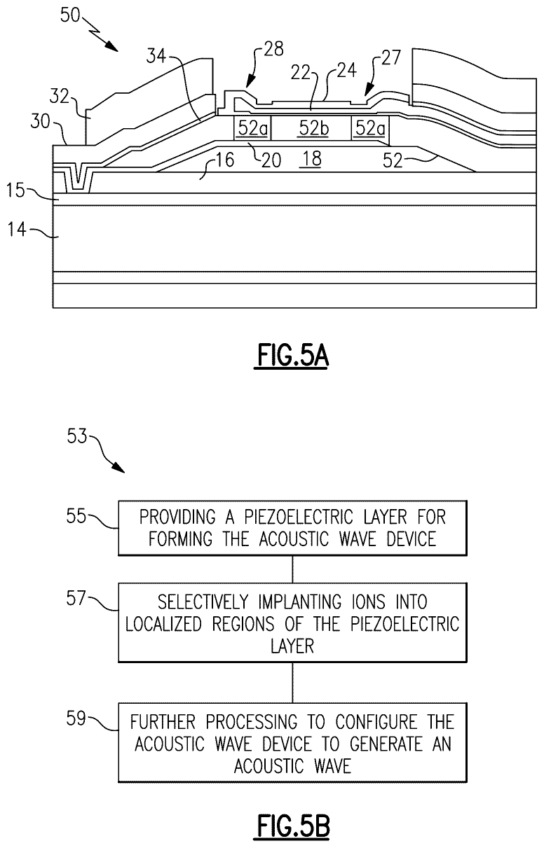

As one example, FIG. 5A is a cross sectional diagram of a bulk acoustic wave (BAW) device having a locally modified piezoelectric material property, according to embodiments. The illustrated BAW device 50 has various features that are arranged substantially similarly to those described above with respect to the BAW device 10 in FIG. 1A, including a support substrate 14, a trap rich layer 15, a first passivation layer 16, an air cavity 18, a first electrode 20, a second electrode 22, and a second passivation layer 24. The BAW device 50 also includes a recessed frame structure 27 and a raised frame structure 28. The BAW device 50 also includes a piezoelectric layer 52 positionally arranged in a similar manner as the piezoelectric layer 12 of the BAW device 10 (FIG. 1A). However, unlike the BAW device 10 described above with respect to FIG. 1A, the piezoelectric layer 52 of the BAW device 50 has localized regions 52a having atoms implanted therein. In the illustrated embodiment, the localized regions 52a of the piezoelectric layer 52 can be implanted with atoms such that the material-coupling coefficient (kₜ²) is locally modified or adjusted, e.g., locally reduced, relative to the bulk regions 52b of the piezoelectric layer 52. In particular, the localized regions 52a are formed at edge regions of an active area of the BAW device 50. As described herein, an active area refers to an area including the piezoelectric layer 52 in which the first and second electrodes 20, 22 overlap in the vertical direction.

In the illustrated embodiment, the localized regions 52a correspond to regions within the piezoelectric layer 12 that correspond to edge regions of the frame structure. In some implementations, the localized regions 52a at least partly overlap with the frame structure. In some implementations, the localized regions 52a are laterally disposed within the frame structure. Reduction of the kₜ² at the edge regions as illustrated can advantageously result in, among other technical effects, a reduction of laterally leaking waves. It will be appreciated that laterally leaking waves can constitute a major loss mechanism for BAW devices. By reducing the lateral leakage, the overall performance including the Q of the BAW device 50 can be improved.

FIG. 5B illustrates a method of fabricating a bulk acoustic wave (BAW) device having a locally modified piezoelectric material property, according to an embodiment. The method 53 includes providing 55 a piezoelectric layer 52 (FIG. 5A) for forming the acoustic wave device and selectively implanting 57 ions into localized regions 52a (FIG. 5A) of the piezoelectric layer. The method additionally includes further processing 59 to configure the acoustic wave device to generate an acoustic wave.

Referring back to FIG. 5A, the localized regions 52a can be formed, e.g., after deposition of the base piezoelectric layer 52, and prior to formation of the second electrode 22 thereover. For example, after depositing the base piezoelectric layer 52, which may initially be uniform, a patterning layer may be formed thereover. The patterning layer may be, e.g., a photoresist layer or a hard mask layer having an opening formed over the regions to be implanted, e.g., over the illustrated localized regions 52a. The remaining portions of the base piezoelectric layer 52 are covered during implantation and remain substantially as the base piezoelectric layer 52b. The openings may be formed, e.g., by spinning a (positive or negative) photoresist, selectively exposing and developing using suitable fabrication techniques. By blocking ions from being implanted outside of the localized regions 52a, the ions may be selectively introduced into the localized regions 52a of the piezoelectric layer 52. After selectively implanting, the patterning layer maybe removed for further processing, e.g., to form the second electrode 22 over the implanted piezoelectric layer 52.

As described herein, the localized regions 52a can be formed by selectively implanting various elements into the piezoelectric layer 52. In particular, locally modifying, e.g., reducing the kₜ², may be performed by implanting different types of ions.

In some embodiments, the kₜ² can be locally reduced by locally inducing amorphization or reducing a degree of crystallinity of the piezoelectric layer 52. When ions penetrate the piezoelectric layer 52, the ions undergo a series of collisions that result in displacement of the target atoms, which in turn can result in formation of point defects. When relatively heavy ions are implanted at sufficiently high dose, the degree of crystallinity of the piezoelectric layer 52 may be substantially reduced due to a relatively high degree of displacement of target atoms. Advantageously, when the implanted ions are inert elements, substantial physical amorphization of the piezoelectric layer 52 may be achieved without affecting the base chemical composition of the piezoelectric layer 52. Thus, according to embodiments, selectively implanting comprises locally reducing a crystallinity of the piezoelectric layer using ions of chemically inert elements, e.g., a noble gas (e.g., He, Kr, Ar, Ne, Xe) or N₂.

For III-V compounds, certain piezoelectric properties can be reduced or degraded by doping with certain elements including group IV elements. According to some embodiments, to reduce the lateral leakage of acoustic waves, for AlN-based piezoelectric materials including AlScN, the inventors have found that kₜ² can be locally reduced by implanting elements certain elements that can be covalently integrated into the lattice of AlN including O, Ar, B, Si and C.

Because ionic collisions during ion implantation can displace different atoms of the target at different probabilities, the stoichiometric ratios of the atoms of the target can change. For example, relatively lighter atoms can be displaced at higher probabilities. To mitigate such effects, according to embodiments, after implanting a dopant, a further implantation can be performed to replenish the target with respect to the atoms that are displaced at higher probabilities. For example, when the target is a piezoelectric layer comprising AlN, the N atoms maybe displaced at a higher rate compared to Al atoms. Thus, according to embodiments, after implanting the piezoelectric layer comprising AlN with a dopant such as an inert gas element or one of O, B, Si and C, the piezoelectric layer may be further implanted with N to replenish or rebalance the stoichiometry.

Acoustic Wave Device with Plurality of Ion-Implanted Piezoelectric Layers

According to some embodiments, a plurality of acoustic wave devices may be integrated on a common substrate. For example, a plurality of acoustic wave resonators may be integrated on a common substrate in different topologies, e.g., ladder, lattice and combined topologies. In some implementations, different acoustic wave resonators may include piezoelectric layers having different piezoelectric material properties. Advantageously, ion implantation can be employed to integrate multiple acoustic wave resonators on the same substrate, where different piezoelectric layers of different acoustic wave resonators can be implanted differently to have different properties, e.g., different material-coupling coefficients (kₜ²).

Accordingly, an acoustic wave device according to embodiments include a plurality of piezoelectric layers formed over a common substrate, where different ones of the piezoelectric layers are implanted differently. The acoustic wave device additionally includes electrodes formed over the piezoelectric layers and configured to generate an acoustic wave.

The localized regions have a locally modified piezoelectric material property. The locally modified piezoelectric material property can include, among other things, piezoelectric constants, piezoelectric coefficients, the dielectric constant, piezoelectric coupling coefficients, elastic modulus, thermal expansion coefficient, acoustic velocity and loss angle tangent, to name a few.

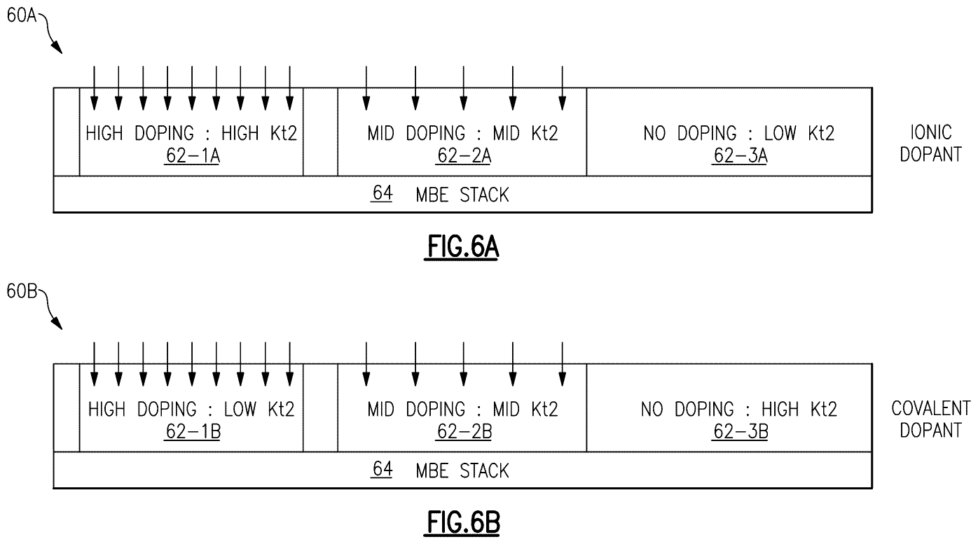

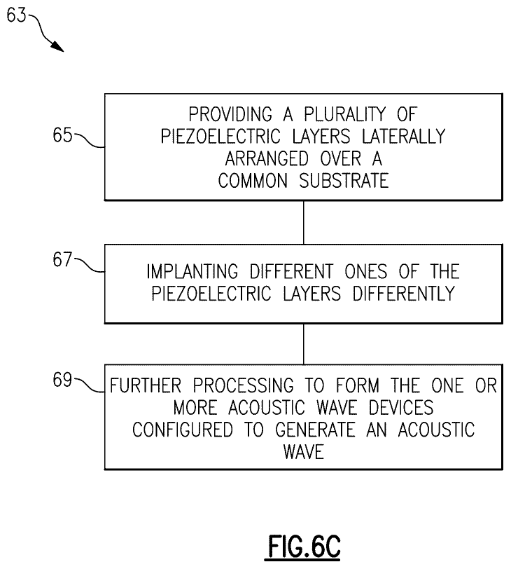

FIGS. 6A and 6B are a cross sectional diagrams of intermediate device structures illustrating a method of fabricating acoustic wave devices each having a plurality of acoustic wave resonators, according to embodiments. The intermediate device structures 60A, 60B may represent those of, e.g., an acoustic wave device having a plurality of resonators that have differently doped piezoelectric layers. The acoustic wave resonator may be, e.g., a BAW device similar to that described above with respect to FIGS. 1A and 1B. The illustrated device structures 60A, 60B show intermediate structures after forming the piezoelectric layers. For illustrative purposes, the device structure 60A shows three differently doped piezoelectric layers 62-1A, 62-2A and 62-3A. Similarly, the device structure 60B shows three differently doped piezoelectric layers 62-1B, 62-2B and 62-3B. However, embodiments are not so limited, and it will be appreciated that as few as two or greater than three differently doped layers may be present.

FIG. 6C illustrates a method of fabricating an acoustic wave device having a plurality of acoustic wave resonators, according to an embodiment. The method 63 of fabricating one or more acoustic wave devices includes providing 65 a plurality of piezoelectric layers over a common substrate, where different ones of the piezoelectric layers arranged to form different acoustic wave devices. The method 65 additionally includes implanting 67 different ones of the piezoelectric layers differently. The method additionally includes further processing 69 to form the one or more acoustic wave devices configured to generate an acoustic wave.

The plurality of piezoelectric layers over a common substrate as illustrated in device structures 60A and 60B may be formed by providing over the bottom electrode layer 64 a base piezoelectric layer and differently implanting different regions thereof to form the piezoelectric layers 62-1A, 62-2A and 62-3A in the intermediate device structure 60A and the piezoelectric layers 62-1B, 62-2B and 62-3B in the intermediate device structure 60B. Differently implanting the different regions can in turn be achieved by sequentially exposing some of the piezoelectric layers and implanting into exposed ones of the piezoelectric layers while covering remaining ones of the piezoelectric layers. For example, when one of the piezoelectric layers 62-1A, 62-2A and 62-3A are being implanted, the remaining two of the piezoelectric layers 62-1A, 62-2A and 62-3A would be covered with a masking layer, e.g., photoresist. Similarly, when one of the piezoelectric layers 62-1B, 62-2B and 62-3B are being implanted, the remaining two of the piezoelectric layers 62-1B, 62-2B and 62-3B would be covered with a masking layer, e.g., photoresist. As illustrated, some of the piezoelectric layers (e.g., 62-3A, 62-3B) may not be implanted such that the as-deposited compositions are preserved. In this way, the different ones of the piezoelectric layers can be implanted differently to have different piezoelectric material properties relative to each other.

After being differently implanted, the device structures 60A and 60B can be further processed and arranged substantially similarly to e.g., the BAW device 10 described above with respect to FIG. 1A, including a second electrode 22, a second passivation layer 24, a recessed frame structure 27, a raised frame structure 28.

In the illustrated embodiment of FIG. 6A, the piezoelectric layers 62-1A, 62-2A and 62-3A are differently doped with a dopant that increases the material-coupling coefficient (kₜ²). In the illustrated embodiment, one or more of the piezoelectric layers 62-1A, 62-2A and 62-3A may be undoped. For example, when the piezoelectric layers comprise an AlN-based material, the implanted atoms can include an element selected from the group consisting of Cr, Sc, Y, Mg, Zr and Hf.

In contrast, in the illustrated embodiment of FIG. 6B, the three differently doped piezoelectric layers 62-1B, 62-2B and 62-3B are differently doped with a dopant that decreases the material-coupling coefficient (kₜ²). In the illustrated embodiment, one or more of the piezoelectric layers 62-1B 62-2B and 62-3B may be undoped. For example, when the piezoelectric layers comprise an AlN-based material, the implanted atoms include an element selected from the group consisting of O, Ar, B, Si and C.

Furthermore, in some embodiments, as described above, the kₜ² can also be locally reduced by locally inducing amorphization or reducing a degree of crystallinity of the piezoelectric layers. When the implanted ions are inert elements, substantial amorphization of the piezoelectric layers may be achieved without affecting the base chemical composition of the piezoelectric layers. Thus, according to embodiments, selectively implanting comprises locally reducing a crystallinity of the piezoelectric layer using ions of chemically inert gases, e.g., a noble gas or N₂.

While FIG. 6A shows piezoelectric layers 62-1A, 62-2A and 62-3A that are either undoped or doped to increase the kₜ² and FIG. 6B shows piezoelectric layers 62-1B, 62-2B and 62-3B that are either undoped or doped to decrease the kₜ², embodiments are not so limited. In other embodiments, some piezoelectric layers may be doped to increase the kₜ² while others may be doped to decrease the kₜ².

Furthermore, as described above, when the target comprises AlN, the N atoms maybe displaced at higher rate compared to Al atoms. Thus, according to embodiments, after implanting the piezoelectric layer comprising AlN with a dopant such as an inert gas element or one of O, Ar, B, Si and C, the piezoelectric layer may be further implanted with N to replenish or rebalance the stoichiometry.

### Wafer-Level Ion Beam Modification of Piezoelectric Layer

As discussed above, base piezoelectric layers may be formed on substrates using deposition techniques such as physical vapor deposition. For example, AlN may be formed by reactive sputtering of Al targets in an N₂ atmosphere. Similarly, AlScN may be formed by reactive sputtering of AlSc targets in an N₂ atmosphere. However, the deposited base piezoelectric layer may exhibit compositional nonuniformity due to a variety of factors, including temperature nonuniformity of the target, compositional nonuniformity of the target, electric and magnetic field nonuniformity across the target, and the temperature nonuniformity of the substrate, among other factors. However, even if these factors are minimized, physical vapor deposition may still result in substantially nonuniform composition of the deposited film. Without being bound to any theory, one reason may be due to the angular dependence of the evaporated flux of atoms from a sputtering target. Without being bound to any theory, the flux of material evaporating from a circular area of a sputtering target at a uniform temperature can exhibit a cosine angular distribution, with the maximum flux directed in a direction normal to the surface of the emitting area. The arrival rate onto a substrate, also referred to as an impingement rate, can be approximated as a cosine angular distribution to account for the relative positions and orientations of the substrate and emitting areas. The resulting compositional variation can in turn cause different acoustic wave devices fabricated on the same wafer with nominally the same piezoelectric layer to have variable piezoelectric characteristics arising from the compositional variations. Thus, there is a need for mitigating or substantially eliminating the within-wafer variation of the composition of piezoelectric layer and the resulting variation in piezoelectric properties. To address these and other needs, a method of fabricating an acoustic wave device comprises providing a piezoelectric layer over a substrate, e.g., using physical vapor deposition, and blanket-implanting ions into the piezoelectric layer, e.g., to mitigate an incoming within-wafer variability in composition or piezoelectric property.

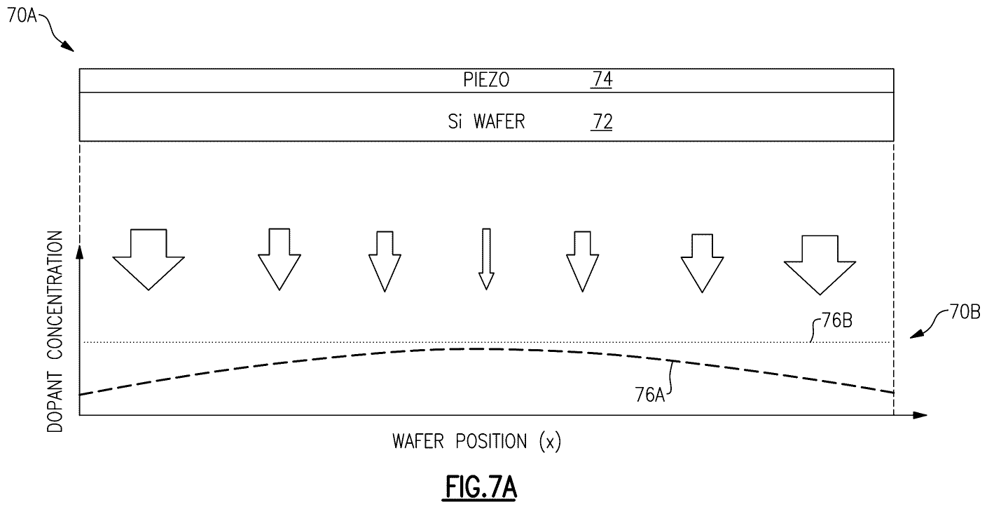

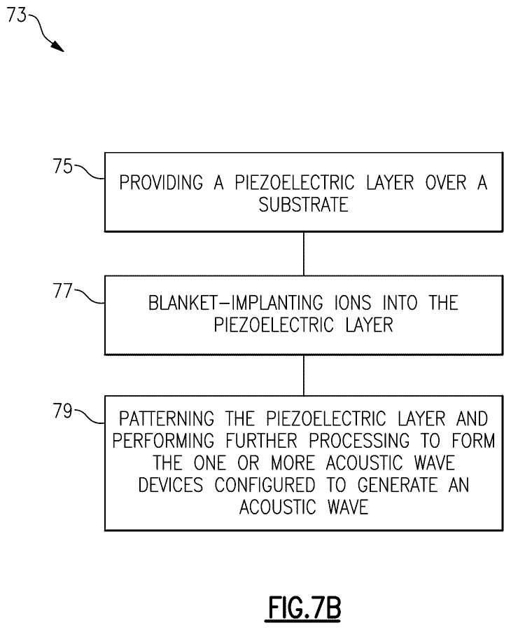

FIG. 7A illustrates adjustment of within-wafer concentration of an element of a piezoelectric layer, e.g., a dopant element. The upper diagram depicts an intermediate structure 70A including a substrate 72 having a base piezoelectric layer 74 formed thereon. The lower diagram shows a graph 70B showing a dopant concentration profile as a function of wafer position for the intermediate structure 70A. The concentration profile 76A schematically represents an as-deposited concentration profile of an element, such as a dopant, of the piezoelectric layer 74. The concentration profile 76B schematically represents a concentration profile of the element of the piezoelectric layer 74 after being adjusted using ion implantation.

FIG. 7B illustrates a method of fabricating an acoustic wave device. The method 73 comprises providing 75 a piezoelectric layer over a substrate. The method additionally includes blanket-implanting 75 ions into the piezoelectric layer. The method further includes patterning the piezoelectric layer and further processing to form the one or more acoustic wave devices configured to generate an acoustic wave. Further processing includes patterning the piezoelectric layer and forming electrodes over the patterned piezoelectric layer to form the one or more acoustic wave devices configured to generate an acoustic wave.

In some embodiments, the implanted ions comprise ions of an element that is not present in the piezoelectric layer prior to blanket-implanting. Such may be the case when primary doping is achieved by, e.g., implanting Sc into a base AlN piezoelectric material. In the embodiments, a secondary dopant may supplement the primary dopant.

In some embodiments, the implanted ions comprise ions of an element that is already present in the base piezoelectric layer prior to blanket-implanting. Such maybe the case when a base doping is achieved in situ during deposition, while the subsequent implantation may be used to improve the uniformity of the dopant concentration in the piezoelectric layer. For example, the base doping of AlN with Sc may be achieved during reactive sputtering to form, e.g., AlScN, while the subsequent implantation may be used to improve the within-wafer uniformity of Sc.

The as deposited piezoelectric layer may have a degree of composition nonuniformity with respect to an element, e.g., a dopant, prior to blanket-implanting. Adjusting the concentration profile of the piezoelectric layer by blanket-implanting comprises implanting the element to reduce the degree of the composition nonuniformity. One such example is illustrated in FIG. 7A, where the initial concentration profile 76A has a gradient in dopant concentration that increase toward the center of the substrate, and the final concentration profile 76B has a substantially reduced or substantially no gradient.

In some implementations such as that illustrate in FIG. 7A, blanket-implanting comprises implanting a higher dose of an element at one of a central region or an edge region of the piezoelectric layer relative to the other of the central region or the edge region. In these implementations, the one of the central region or the edge region has a lower concentration of the element relative the other of the central region or the edge region prior to blanket-implanting.

In some embodiments, the piezoelectric material property that is adjusted for improved uniformity comprises a material-coupling coefficient (kₜ²). In some embodiments, modifying the piezoelectric material property comprises increasing the kₜ² of a region of the piezoelectric layer relative to the other regions of the piezoelectric layer. In these embodiments, where the piezoelectric layer comprises an AlN-based material, the blanket-implanted ions comprise one or more of Cr, Sc, Y, Mg, Zr and Hf. In some other embodiments, modifying the piezoelectric material property comprises decreasing the kₜ² of the region of the piezoelectric layer relative to the other regions of the piezoelectric layer. In these embodiments, where the piezoelectric layer comprises an AlN-based material, the blanket-implanted ions comprise one or more of O, Ar, B, Si and C.

In the illustrated example of FIG. 7A, the degree if composition nonuniformity is reduced with respect to a dopant such as Sc. In the illustrated initial concentration profile 76A, the as-deposited concentration profile of the dopant shows a relatively higher concentration in the central region. Such profile may occur for a dopant profile, e.g., a Sc profile, from physical vapor deposition of AlScN by reactive sputtering. The arrows having different widths qualitatively represent different doses of the dopant, e.g., Sc, with larger width representing higher dose. The illustrated arrows depict a higher implantation dose towards edge regions of the wafer relative to the central region of the wafer. As illustrated, in some embodiments, the as-deposited piezoelectric layer comprises a concentration gradient with respect to a dopant element, e.g., Sc, and blanket-implanting dopant ions into the piezoelectric layer comprises at least partly or substantially reducing the concentration gradient of the dopant.

In some embodiments, the compensation for uneven dopant concentration at different regions of the target piezoelectric layer may be achieved by controlling the ion beam current. For example, the ion current can be increased at regions that are to receive higher doses of the implanted ions relative to regions that are to receive lower doses.

In some other embodiments, the compensation for uneven dopant concentration at different regions of the target piezoelectric layer may be achieved by using a masking layer, e.g., a photoresist layer. For example, the masking layer may partially block the ions from being implanted in regions where the base concentration is relatively high.

### Ion Implantation for Temperature Compensation Layer of Acoustic Wave Device

Acoustic wave devices can include a temperature compensation layer. Such a temperature compensation layer can bring the temperature coefficient of frequency (TCF) of an acoustic wave device closer to zero relative to a similar acoustic wave device without the temperature compensation layer. The temperature compensation layer can have a positive TCF. This can compensate for a piezoelectric layer of the acoustic wave device having a negative TCF.

Implanting ions into a temperature compensation layer can enhance material properties. For example, boron and/or phosphorus can be implanted into a fused silica temperature compensation layer to enhance temperature compensation properties. An implanted species can boost temperature compensation. With an implanted species, a thinner temperature compensation layer can be used to achieve the same level of temperature compensation as temperature compensation layer that is similar expect without the implanted species. A drop in quality factor and/or electromechanical coupling coefficient due to a temperature compensation layer can be reduced with an implanted species.

Ion implantation to introduce an implanted species in a temperature compensation layer can be performed without the use of expensive or difficult to manufacture targets containing multiple metal ions. Ion implantation can introduce an implanted species into a temperature compensation layer at a low and precise doping level. The ion implantation technique allows for the surgical implantation of specific ions to modify the local chemistry in a desired region. Using ion implantation can introduce implanted species with less variation than other processes, such as chemical vapor deposition (CVD).

Ions can be implanted in a temperature compensation layer of a variety of acoustic wave resonators including, but not limited to, BAW resonators such as FBARs and/or BAW SMRs, SAW resonators, TC SAW resonators, MPS SAW resonators, Lamb wave resonators, and boundary wave resonators. Such acoustic wave resonators can be included in an acoustic wave filter that filters a radio frequency signal.

Ions can be implanted in a temperature compensation layer of an acoustic wave device of an oscillator. Such an oscillator can benefit from precision temperature compensation. Example acoustic wave devices of an oscillator can include but are not limited to a BAW device, a SAW device, a TC SAW device, an MPS SAW device, a Lamb wave device, or a boundary wave device.

An acoustic wave device can include a temperature compensation layer formed with ion implantation in accordance with any suitable principles and advantages disclosed herein and a piezoelectric layer formed with ion implantation in accordance with any suitable principles and advantages disclosed herein.

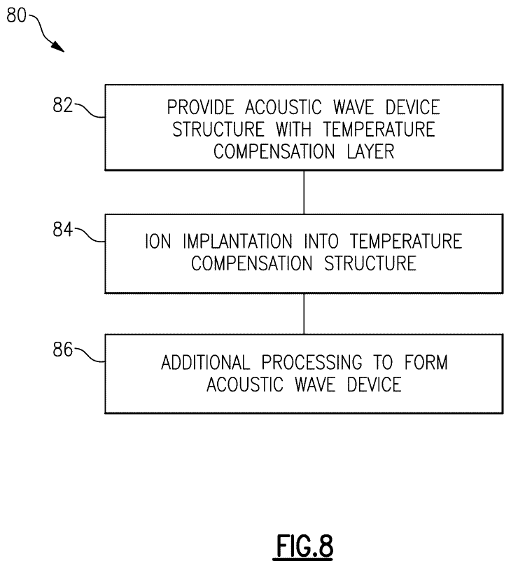

FIG. 8 is a flow diagram of a method 80 of manufacturing an acoustic wave device with temperature compensation. In the method 80, ion implantation can enhance temperature compensation of a temperature compensation layer of an acoustic wave device. The acoustic wave device can be a BAW device. The acoustic wave device can be any other suitable acoustic wave device, such as a SAW device, a boundary acoustic wave device, or the like. The method 80 can be performed in manufacturing multiple acoustic wave devices concurrently.

At operation 82, an acoustic wave device structure that includes a temperature compensation layer is provided. The temperature compensation layer can be a silicon dioxide layer. Such a temperature compensation layer can have a thickness that is 120 nanometers or less, such as a thickness in a range from 5 nanometers to 120 nanometers or a thickness in a range from 30 nanometers to 120 nanometers. The temperature compensation layer can include any other suitable temperature compensation layer. The acoustic wave device structure includes one or more additional layers of an acoustic wave device. For example, the acoustic wave device structure can include a piezoelectric layer in physical contact with the temperature compensation layer. This example acoustic wave device structure can also include one or more of an electrode, a support substrate, and an acoustic reflector. As another example, the acoustic wave device structure can include at least a portion of an electrode. In this example, the temperature compensation layer can be in physical contact with the electrode.

Ion implantation can implant a dopant in the temperature compensation layer at operation 84. The dopant can be referred to as an implanted species. Ion implantation can introduce a precise doping concentration of the dopant in the temperature compensation layer. After the ion implantation, the doping concentration of the dopant in the temperature compensation layer can be less than 20%, less than 10%, less than 15%, less than 5%, less than 2%, less than 1%, less than 0.5%, or less than 0.2%. The dopant can include, but is not limited to, boron, phosphorous, tellurium, titanium, germanium, fluorine, or carbon.

In certain applications, ion implantation at operation 84 can implant a dopant into temperature compensation layers of a plurality of acoustic wave devices in a single processing step. The plurality of acoustic wave devices can be on a common die. According to various applications, two or more ion implantation operations can be performed to introduce two or more dopants into a temperature compensation layer and/or to create two or more doping concentrations of a dopant in different temperature compensation layers of different acoustic wave devices.

Additional processing can be performed to form an acoustic wave device at operation 86. The additional processing can include forming one or more layers and/or functional structures of the acoustic wave device. For example, the additional processing can include forming an electrode layer over the temperature compensation layer. This can result in the temperature compensation layer being positioned between the piezoelectric layer and an electrode. Alternatively or additionally, forming the electrode layer can result in the temperature compensation layer being embedded in an electrode of the acoustic wave device. As another example, the additional processing can include forming a piezoelectric layer over the temperature compensation layer. This can result in the temperature compensation layer being positioned between the electrode layer and the piezoelectric layer. As one more example, the additional processing can include forming a passivation layer. After the additional processing at operation 86, an acoustic wave device can be fully formed.

A temperature compensation layer can include silicon dioxide. Such a silicon dioxide layer can also be referred to as amorphous silica or fused silica in various applications. A silicon dioxide temperature compensation layer can have a thickness that is less than 120 nanometers (nm). In certain applications, the thickness can be in a range from 5 nm to 120 nm. According to some of these applications, the thickness can be in a range from 30 nm to 120 nm. A temperature compensation layer can be included in a BAW device. The temperature compensation layer can be in physical contact with a piezoelectric layer and/or an electrode of a BAW device. The temperature compensation layer can be located between a piezoelectric layer and an electrode of a BAW device. The temperature compensation layer can be embedded in an electrode of a BAW device. Example implanted species include, but are not limited to one or more of boron, phosphorus, tellurium, titanium, germanium, fluorine, or carbon. Ion implantation can be performed without a photoresist after temperature compensation layer deposition. Example BAW devices that include an ion implanted temperature compensation layer will be discussed with reference to FIGS. 8 to 12.

FIG. 9 is a cross sectional diagram of a BAW device 90 according to an embodiment. The BAW device 90 and/or any other BAW device disclosed herein can be a BAW resonator. The BAW device 90 includes a temperature compensation layer 91 with an implanted species. In the BAW device 90, the temperature compensation layer 91 can include an implanted species from ion implantation in accordance with any suitable principles and advantages disclosed herein. The temperature compensation layer 91 is physically different than other temperature compensation layers that are not manufactured using ion implantation.

The BAW device 90 is similar to the BAW device 10 of FIG. 1A, except that the temperature compensation layer of the BAW device 90 includes an implanted species. The BAW device 90 can include an ion implanted piezoelectric layer in certain applications. The BAW device 90 can include a piezoelectric layer that is not implanted with ions in some other applications. In various applications, ion implantation can introduce a dopant into the first passivation layer 16 and/or the second passivation layer 24 in accordance with any suitable principles and advantages disclosed herein. Such ion implantation can enhance temperature compensation in the BAW device 90.

The temperature compensation layer 91 can bring the TCF of the BAW device 90 closer to zero. The temperature compensation layer 91 can produce a positive TCF. The doping concentration of an implanted species in the temperature compensation layer 91 can be less than 20%, less than 15%, less than 10%, less than 5%, less than 2%, less than 1%, or less than 0.5%. The implanted species can include one or more of boron, phosphorous, tellurium, titanium, germanium, fluorine, or carbon. The temperature compensation layer 91 can be in physical contact with the piezoelectric layer 12. The temperature compensation layer 91 can be in physical contact with an electrode of the BAW device (e.g., the second electrode 22 in FIG. 9). The temperature compensation layer 91 can include an implanted species therein from ion implantation. As illustrated, the temperature compensation layer 91 is positioned between an electrode of the BAW device 90 (e.g., the second electrode 22 in FIG. 9) and the piezoelectric layer 12. TC BAW devices can include a temperature compensation layer (1) between a piezoelectric layer and upper electrode (e.g., as illustrated in FIG. 9), (2) between the piezoelectric layer and lower electrode, (3) embedded within a piezoelectric layer, (4) embedded within an electrode, or (5) any suitable combination of (1) to (4).

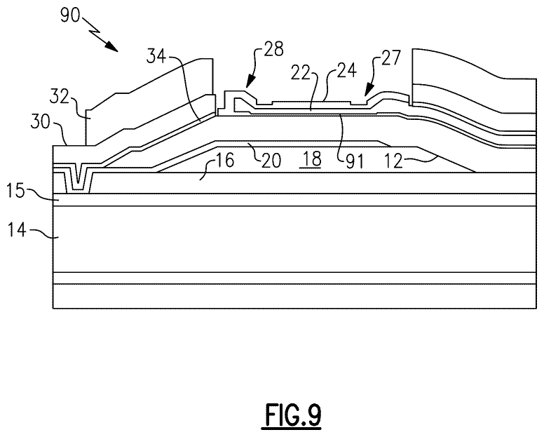

FIG. 10 is a cross-sectional diagram of a BAW device 92 according to an embodiment. The BAW device 92 includes a suspended raised frame structure 93 and an air bridge 94. Metal layer 95 is over the air bridge 94. The BAW device 92 can achieve one or more of a relatively high quality factor at anti-resonance (Qp), relatively low lateral spur, or relatively low non-linearity. An acoustic wave filter that includes one or more BAW devices 92 can achieve a relatively sharp filter skip and/or a relatively wide passband.

The BAW device 92 includes a temperature compensation layer 91 with an implanted species. As illustrated, the temperature compensation layer 91 is included between an electrode (e.g., second electrode 22) and a piezoelectric layer 12 in a main acoustically active region of the BAW device 92.

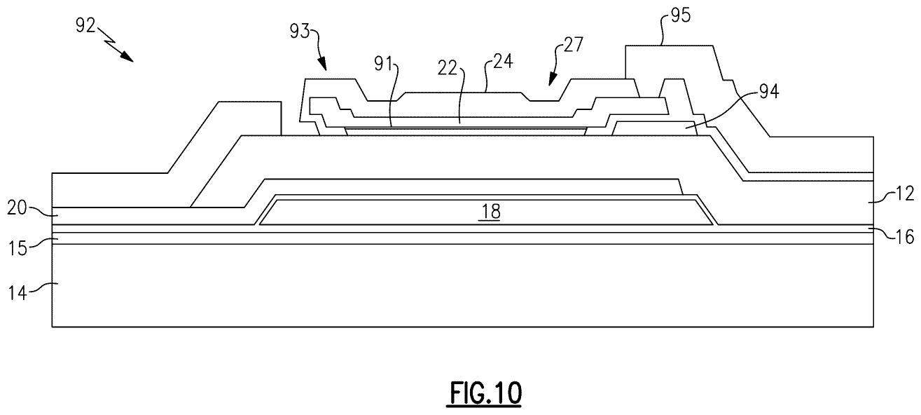

FIG. 11 is a cross-sectional view of a portion of a temperature compensated BAW (TCBAW) device 96 according to an embodiment. The TCBAW device 96 includes a temperature compensation layer 91 positioned between a piezoelectric layer 12 and a second electrode layer 22. As illustrated in FIG. 11, the temperature compensation layer 91 is in physical contact with the piezoelectric layer 12. The temperature compensation layer 91 can be in physical contact with the second electrode 22 as illustrated. The temperature compensation layer 91 can include an implanted species.

Passivation layers 24 and/or 97 of the TCBAW device 96 can include one 92 or more implanted species in certain instances. A raised frame structure of the BAW device 96 can include an oxide raised frame layer 98. The oxide raised frame layer 98 can include silicon dioxide. In some applications, the BAW device 96 includes electrodes 20 and 22 that include ruthenium and a piezoelectric layer 12 that includes aluminum nitride.

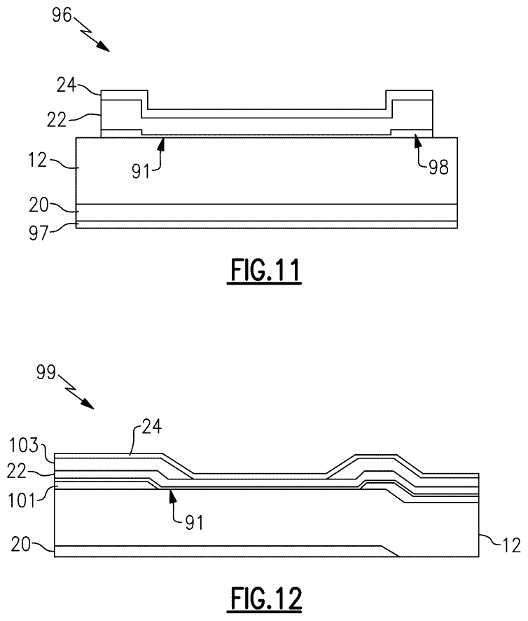

FIG. 12 is a cross-sectional view of a portion of a TCBAW device 99 according to an embodiment. The TCBAW device 99 includes a temperature compensation layer 91 positioned between a piezoelectric layer 12 and a second electrode layer 22. The temperature compensation layer 91 can include an implanted species. The TCBAW device 99 also includes a raised frame structure that includes an oxide raised frame layer 101 and a metal raised frame layer 103. The raised frame structure can reduce lateral energy leakage from a main acoustically active region of the TCBAW device 99.

A temperature compensation layer with an implanted species can be implemented in a SAW device. Certain SAW devices include a temperature compensation layer over and in physical contact with an interdigital transducer (IDT) electrode. Such SAW devices can be referred to as temperature compensated SAW (TCSAW) devices. Multilayer piezoelectric substrate (MPS) SAW devices can include one or more layers that can provide temperature compensation.

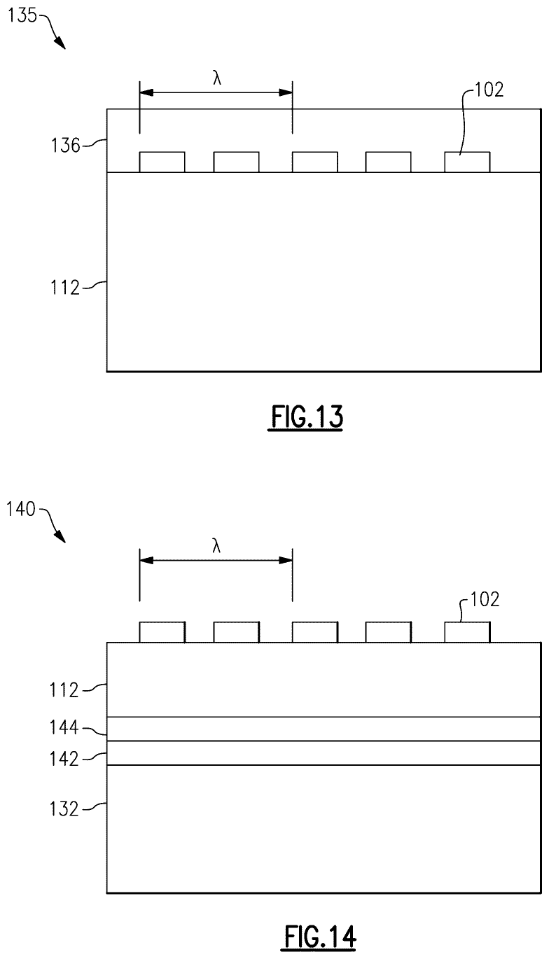

In SAW devices, the temperature compensation layer can be a silicon dioxide layer. Silicon dioxide is a material with an acoustic velocity and an elastic modulus that increase with temperature. This can allow for temperature compensation with piezoelectric materials that have an acoustic velocity and an elastic modulus that decrease with temperature. Ion implantation can enhance temperature compensation in temperature compensation layers in SAW devices. Examples of SAW devices with ion implanted temperature compensation layers will be discussed with reference to FIGS. 13 to 16.

FIG. 13 is a cross-sectional view of the TCSAW device 135 that includes a temperature compensation layer 136 with an implanted species. IDT electrode 102 can be implanted in accordance with any suitable principles and advantages of FIG. 2A.

The TCSAW device 135 of FIG. 13 is like the TCSAW device 120 of FIG. 3, except that the temperature compensation layer 136 includes an implanted species from ion implantation. The temperature compensation layer 136 can be implemented in accordance with any suitable principles and advantages of the temperature compensation layer 91 of BAW devices disclosed herein. The implanted species can increase temperature compensation and/or reduce thickness of the temperature compensation layer 136 compared to a temperature compensation layer without the implanted species. The implanted species in the temperature compensation layer 136 can increase temperature compensation relative to a temperature compensation layer that is otherwise similar except for not including the implanted species. In some other applications, the temperature compensation layer 136 can be thinner than a temperature compensation layer that is otherwise similar except for not including the implanted species.

FIG. 14 is a cross-sectional view of an MPS SAW device 140 according to an embodiment. The illustrated MPS SAW device 140 includes a multilayer piezoelectric substrate including a support substrate 132, a trap rich layer 142, a temperature compensation layer 144, and a piezoelectric layer 112. The MPS SAW device 140 also includes an IDT electrode 102 on the piezoelectric layer 112. The temperature compensation layer 144 includes an implanted species. The temperature compensation layer 144 can be implemented in accordance with any suitable principles and advantages of the temperature compensation layer 136 of SAW devices disclosed herein and/or the temperature compensation layer 91 of BAW devices disclosed herein.

The piezoelectric layer 112 can be a lithium tantalate layer in the MPS SAW device 140. In certain applications, the piezoelectric layer 112 can be thinner in the MPS SAW device 140 compared to in the TCSAW device 135. For example, the piezoelectric layer 112 can have a thickness of less than λ in the MPS SAW device 140, in which λ is a wavelength of a surface acoustic wave generated by the MPS SAW device 140. In some other instances, the piezoelectric layer 112 can have a thickness on the order of 10s of λ, in which λ is a wavelength of a surface acoustic wave generated by the MPS SAW device 140.

The support substrate 132 can be a semiconductor substrate, such as a silicon substrate. The support substrate 132 can be a high resistivity silicon substrate. The support substrate 132 can have a crystalline structure. The trap rich layer 142 can be a polysilicon layer, an amorphous silicon layer, or the like. The trap rich layer 142 can have a reduced carrier mobility relative to the support substrate 132. The trap rich layer 142 can trap free charge carriers to reduce spurious radio frequency current due to electric fields of the MPS SAW device 140.

The temperature compensation layer 144 can be a buried layer. The temperature compensation layer 144 is positioned between the trap rich layer 142 and the piezoelectric layer 112 in the MPS SAW device 140. The temperature compensation layer 144 is in physical contact with the trap rich layer 142 as illustrated in FIG. 14. More generally, a temperature compensation layer with an implanted species can be positioned between a support substrate and a piezoelectric layer in an MPS stack. One or more layers can be positioned between a temperature compensation layer and the support substrate in an MPS SAW stack in certain applications. Alternatively or additionally, one or more layers can be positioned between a temperature compensation layer and the piezoelectric layer in an MPS SAW stack in certain applications.

FIG. 15 is a cross-sectional view of an MPS SAW device 150 according to another embodiment. In the MPS SAW device 150, a temperature compensation layer 136 that includes an implanted species is included over the IDT electrode 102. The piezoelectric layer 112 in the MPS SAW device 150 can be a lithium niobate layer. In some instances (not illustrated), on or more intervening layers can be included between the piezoelectric layer 112 and the support substrate 132 in the MPS SAW device 150. Non-limiting examples of a layer of the one or more additional layers include an adhesion layer, a dispersion adjustment layer, and a thermal dissipation layer. In the MPS SAW device 150, the support substrate 132 can be a semiconductor substrate, a silicon substrate, a ceramic substrate, a polycrystalline spinel substrate, a quartz substrate, a sapphire substrate, a borosilicate substrate, a glass substrate, or any other suitable substrate. A support substrate can include any of these support substrates in other MPS SAW devices and/or BAW devices as suitable.

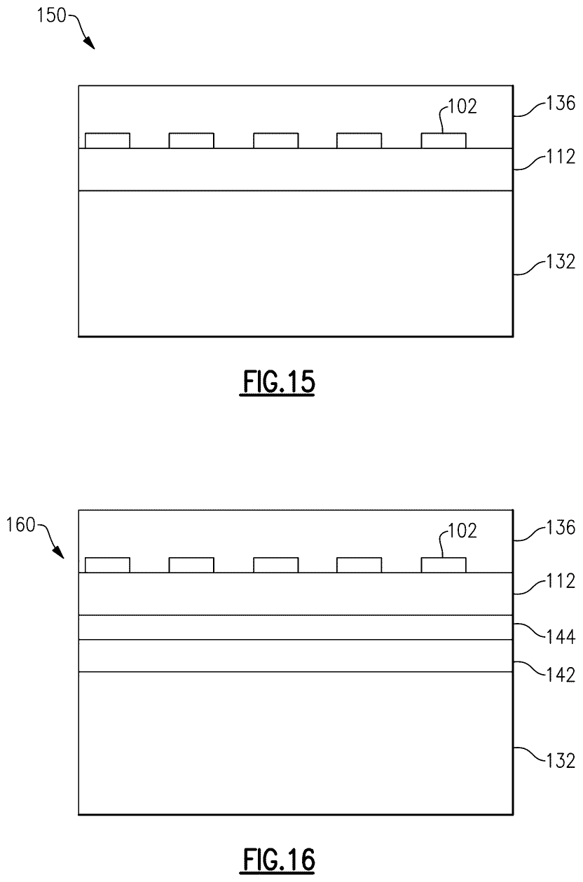

FIG. 16 is a cross-sectional view of an MPS SAW device 160 according to another embodiment. The MPS SAW device 160 includes both (1) a temperature compensation layer 136 that includes an implanted species and (2) a temperature compensation layer 144 that includes an implanted species and positioned between a trap rich layer 142 and a piezoelectric layer 112. In the MPS SAW device 160, the temperature compensation layers 136 and 144 can include the same implanted species or different implanted species. In the MPS SAW device 160, the temperature compensation layers 136 and 144 can include the substantially a same doping concentration and/or different doping concentrations.

### Ion Implantation for Mass Loading of Bulk Acoustic Wave Device

Acoustic wave filters with BAW resonators having a plurality of different resonant frequencies can meet a variety of design specifications including insertion loss at a pass band edge, rejection outside of a passband of the BAW filter, power handling, and matching to a power amplifier and/or a low noise amplifier. Manufacturing BAW resonators with a plurality of different resonant frequencies with more reliable and/or a lower complexity process is desirable. Ion implantation can be used to adjust mass loading of BAW resonators. The mass loading adjustment from ion implantation can be a relatively small amount. Ion implantation can be performed on one or more electrode layers and/or one or more other layers of a BAW resonator.

A mass load can tune resonant frequency of a BAW resonator. Increasing a mass load can decrease the resonant frequency. On the other hand, decreasing the mass load can increase the resonant frequency.

Any two BAW resonators of a filter can be tuned differently by having mass loads. For example, two series BAW resonators of a filter can have mass loads with different masses. As another example, two shunt BAW resonators of a filter can have mass loads with different masses. As one more example, a series BAW resonator and shunt BAW resonator of a filter can have mass loads with different masses.

In some instances, two or more BAW resonators of a filter can have mass loads with the same mass while one or more other BAW resonators of the filter have mass loads with different mass. Such BAW resonators with mass loads with the same mass can have a resonant frequency tuned by a same amount by respective mass loads.

A mass loaded layer impacts the resonant frequency of a BAW resonator. Other layers of the BAW resonator also impact the resonant frequency. Mass loaded layers with different masses can account for some or all of a difference in resonant frequency between two BAW resonators. Differences in mass loading provided by one or more other layers (e.g., one or more electrode layers and/or one or more passivation layers) together with mass loaded layers with different masses can cause BAW resonators to have different resonant frequencies in certain applications. Alternatively, a difference in mass of mass loaded layers can account for an entire difference in resonant frequency between BAW resonators in various applications.

As BAW filter frequencies increase, certain BAW film stacks are getting thinner and so are layers of such BAW resonators. It can be difficult to control mass loading deposition thicknesses below 30 angstrom (Å).

Ion implantation is an alternative to thin mass loading sputtering deposition. With ion implantation, relatively small differences in mass loading can be precisely manufactured to create differences in resonant frequency in a BAW device. Different ion implanted mass load doses can be included in corresponding mass loaded layers of BAW devices. A mass loaded layer can refer to a layer that has an ion implanted mass load dose therein. Ion implantation for mass loading can be performed in one or more suitable layers of a BAW device, such as, but not limited to, one or more of an electrode layer, a passivation layer, or a piezoelectric layer. In certain applications, one or more electrodes of a BAW device can be implanted using ion implantation. An implanted species can match electrode material in some applications. An implanted species can be different than electrode material in some other applications.

Any suitable implanted species for mass loading can be used. Tungsten is an example implanted species for mass loading. Tungsten is relatively heavy and has a relatively small atomic radius. This can lead to better stress control. Other example implanted species include, but are not limited to, molybdenum and ruthenium.

Table 1 below includes examples of elements for mass loading in BAW devices and related parameters.

TABLE 1

| | | | Molar | | | | | |
|---|---|---|---|---|---|---|---|---|
| | | | thickness | | | | | |
| | | Molar | for 1 cm² | ML Film | | ML | | Stress |
| | Density | weight | thickness | thickness | ML Dose | Mass | Atomic | Impact/ |
| Element | (g/cm²) | (g) | (um) | (Å) | (1/cm²) | (μg) | Radius | mass |
| Mo | 10.28 | 95.95 | 9.33E+04 | 10 | 6.45E+15 | 1.03E+00 | 139 | 1.35E+02 |
| Ru | 12.45 | 101.07 | 8.12E+04 | 10 | 7.42E+15 | 1.25E+00 | 134 | 1.08E+02 |
| W | 19.45 | 183.84 | 9.55E+04 | 10 | 6.31E+15 | 1.93E+00 | 139 | 7.22E+01 |

An acoustic wave device can include a piezoelectric layer and/or a temperature compensation layer formed with ion implantation in accordance with any suitable principles and advantages disclosed herein and a mass loaded layer formed with ion implantation in accordance with any suitable principles and advantages disclosed herein.

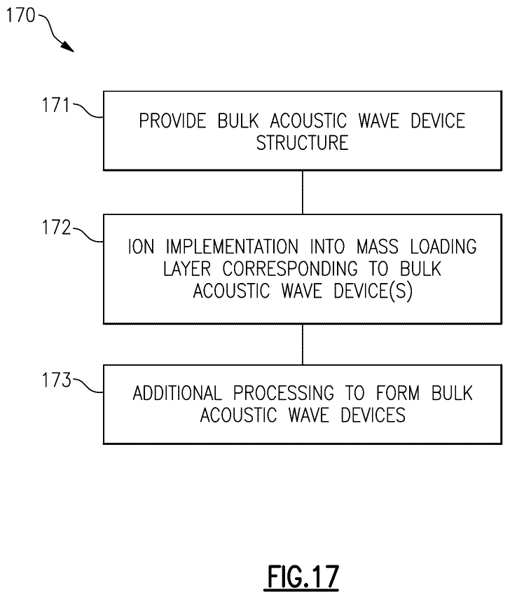

FIG. 17 is a flow diagram of a method 170 of manufacturing bulk acoustic wave devices with mass loading. In the method 170, ion implantation can adjust mass loading of a first BAW device relative to mass loading of a second BAW device. This adjustment in mass loading can contribute to the difference in resonant frequency between the first BAW device and the second BAW device.

At operation 171, a bulk acoustic wave device structure that includes a first layer in a first area corresponding to a first bulk acoustic wave device and a second layer in a second area corresponding to a second bulk acoustic wave device is provided. The first layer and the second layer can each be an electrode layer. In some other applications, the first layer and/or the second layer can be a passivation layer. The first layer and/or the second layer can each have a thickness of 1 μm or less. The acoustic wave device structure can include one or more additional layers of an acoustic wave device.

Ion implantation can implant a dopant in the first layer at operation 172. This can provide an ion implanted mass load dose into the first layer. The first layer can be an electrode layer of a bulk acoustic wave device. The dopant can be referred to as an implanted species. Ion implantation can introduce a precise doping concentration of the dopant in the first layer. The dopant can include the same material as the first layer. The dopant can include different material than the first layer. The dopant can include iridium, osmium, platinum, chromium, tungsten, molybdenum, or ruthenium.

In certain applications, ion implantation at operation 172 can implant a dopant into first layers of a plurality of bulk acoustic wave devices in a single processing step. The plurality of acoustic bulk wave devices can be on a single die. According to various applications, two or more ion implantation operations can be performed to introduce two or more dopants into a layer and/or to create two or more doping concentrations of a dopant in different layers of different bulk acoustic wave devices.

In some applications, one or more additional ion implantations can be performed to implant a dopant into one or more other mass loaded layers. For example, in some applications, implanted species can be introduced into two different electrode layers, an electrode layer and a passivation layer, or two different passivation layers to adjust mass loading of one BAW device relative to another BAW device.

Additional processing can be performed to form bulk acoustic wave devices at operation 173. The additional processing can include forming one or more layers and/or functional structures of the bulk acoustic wave devices. For example, the additional processing can include forming one or more of a piezoelectric layer, an electrode layer, or a passivation layer. After the additional processing at operation 173, BAW devices can be fully formed.

FIG. 18 is a top plan view schematically illustrating a BAW die 180 that includes BAW resonators with different ion implanted mass load doses. BAW resonators of the BAW die 180 can be manufactured in accordance with any suitable principles and advantages disclosed herein. FIG. 18 shows cross-sectional views of material stacks of BAW resonators 186 and 188 of the BAW die 180. The BAW resonators 186 and 188 have different ion implanted mass load doses in mass loaded layers with different masses and/or different densities that impact their respective resonant frequencies. Ion implantation can further increase the mass of an ion implanted mass load dose of the BAW resonator 188 relative to the corresponding ion implanted mass load dose of the BAW resonator 186.

The illustrated material stack of the BAW resonator 186 is located in the main acoustically active region of the respective BAW resonator 186. The illustrated material stack of the BAW resonator 188 is located in the main acoustically active region of the respective BAW resonator 188. FIG. 1B illustrates an example main acoustically active region MAIN. The material stacks can be positioned over an acoustic reflector, such as an air cavity or a solid acoustic mirror. The material stacks can correspond to layers of a BAW device implemented in accordance with any suitable principles and advantages of BAW devices disclosed herein, such as any suitable principles and advantages of the BAW devices of FIGS. 8 to 12.

As shown in FIG. 18, the material stack of the BAW resonator 186 includes a first passivation layer 16, a first electrode 20, a piezoelectric layer 12, a second electrode 22, a second passivation layer 24. As also shown in FIG. 18, the material stack of the BAW resonator 188 includes a first passivation layer 16, a first electrode 20′, a piezoelectric layer 12, a second electrode 22′, a second passivation layer 24. The first electrode 20′ and the second electrode 22′ of the BAW resonator 188 each include an implanted species from ion implantation. This can increase their masses relative to the corresponding layers of the BAW resonator 186. This difference in mass loading can contribute to the BAW resonator 186 having a higher resonant frequency than the BAW resonator 188.

A difference in mass loading between the BAW resonator 186 and 188 can be created by ion implantation of one or more of layers of the material stack.

The BAW resonators 186 and 188 can be included in a single filter. The BAW resonators 186 and 188 can be included in different filters. The different filters can be included in a multiplexer, such as a duplexer. In certain embodiments, the BAW resonators 186 and 188 can be implanted in accordance with any suitable principles and advantages of the BAW devices of FIGS. 8 to 12.

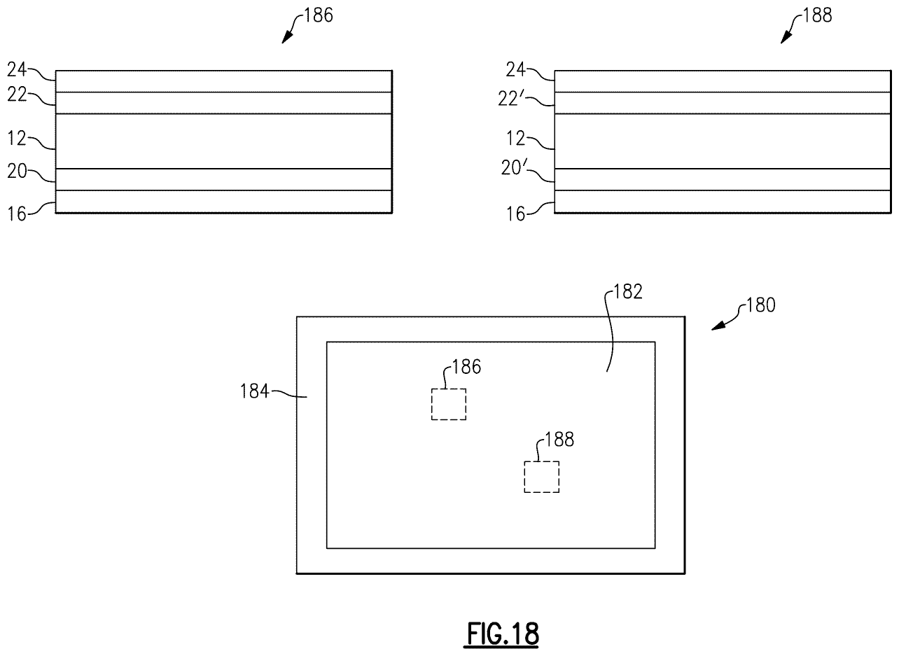

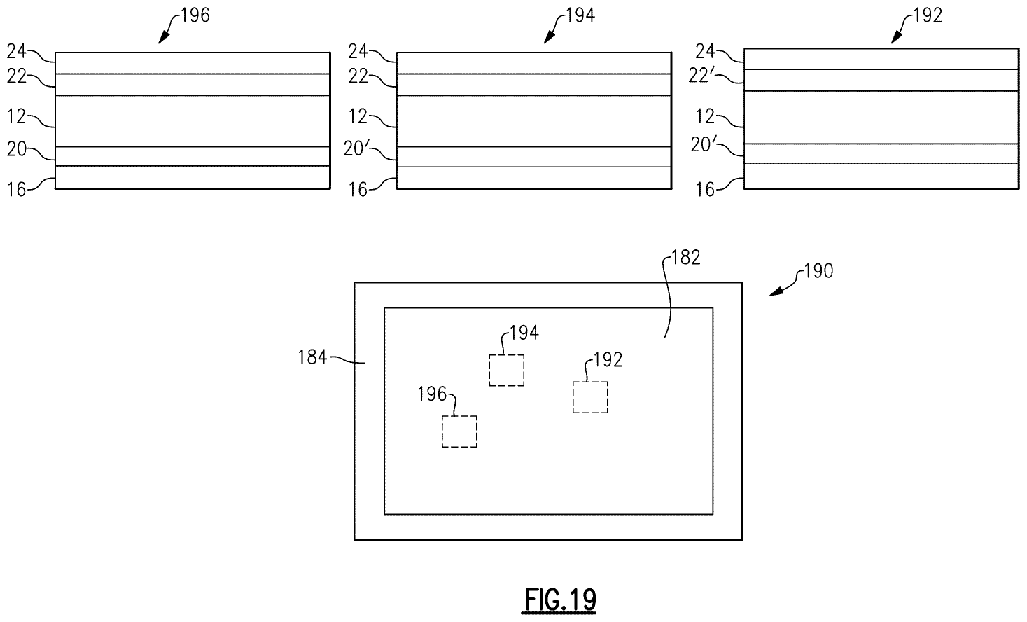

FIG. 19 is a top plan view schematically illustrating a BAW die 190 that includes BAW resonators with different ion implanted mass load doses. BAW resonators of the BAW die 190 can be manufactured in accordance with any suitable principles and advantages disclosed herein. FIG. 19 shows a view of material stacks of BAW resonators 192, 194, and 196 of the BAW die 190. The BAW resonators 192, 194, and 196 have different ion implanted mass load doses that impact their respective resonant frequencies. Ion implantation can adjust mass loading such that the BAW resonators 192, 194, and 196 have different resonant frequencies.

The BAW resonators 192, 194, and 196 can be included in a single filter. Any suitable number of BAW resonators with one or more ion implanted layers to adjust relative mass loading can be included in a single filter. The BAW resonators 192, 194, and 196 can be included in two or more different filters. The different filters can be included in a multiplexer, such as a duplexer or a triplexer. The principles and advantages disclosed herein can be applied to manufacturing BAW resonators on a BAW die, in which the BAW resonators are included in any suitable number of different filters of a multiplexer and/or any suitable number of standalone filters.

Differences in mass loading between the BAW resonators 192, 194, and 196 can be created by one or more of (1) including a dopant in a layer of a BAW resonator that is not included in another BAW resonator, (2) creating different doping concentrations in a corresponding layer of BAW resonators, or (3) including different dopants in a corresponding layer of BAW resonators. Referring to FIG. 19, the BAW resonator 194 includes an ion implanted first electrode 20′ and the BAW resonator 196 includes an ion implanted first electrode 20′ and an ion implanted second electrode 22′. The ion implanted electrodes of the BAW resonators 194 and 196 can adjust mass loading such that the BAW resonators 192, 194, and 196 have different resonant frequencies.

Ion implantation can adjust mass loading in combination with one or more other mass loading techniques. For example, ion implantation can be used to fine tune mass loading and adjusting a layer thickness can be used for coarse tuning of mass loading.

FIG. 20 is a flow diagram for a process 200 of manufacturing BAW resonators. The BAW resonators can be FBARs and/or BAW SMRs. The process 200 includes providing a BAW resonator structure at operation 201. Ion implantation at operation 202 can implant a dopant into one or more layers of a bulk acoustic wave device(s). This can involve implanting a dopant into layers of a plurality of acoustic bulk wave devices on a common die during a single processing step. After ion implantation, an ion implanted mass load dose is included in the one or more layers of the bulk acoustic wave device(s). Ion implantation can be performed to (1) introduce one or more dopants into a layer, (2) create two or more doping concentrations of a dopant in different layers, (3) introduce different dopants in different layers, (4) introduce a dopant into one or more layers and not introduce the dopant into one or more other layers, (5) any suitable combination thereof. After ion implantation, one or more processing operations can be performed to form BAW resonators. BAW resonators are interconnected at operation 203. The interconnecting can include connecting BAW resonators together as a filter. In some instances, interconnecting can include connecting BAW resonators together as two or more filters. In some such instances, interconnecting can include connecting BAW resonators of the two or more filters together at a common node to form a multiplexer, such as a duplexer.

A BAW resonator with one or more ion implanted layers can be included in any suitable filter. The filter can be used to filter a radio frequency signal. The filter can include a plurality of BAW resonators, one or more BAW resonators and one or more other types of acoustic resonators, one or more BAW resonators and an inductor capacitor (LC) circuit, the like or any suitable combination thereof. The filter can be any suitable type of filter, such as band pass filter or a band rejection filter. Band pass filter can be implemented in applications for passing a particular frequency band and rejecting frequencies outside of the particular frequency band. The filter can have any suitable topology, such as a ladder topology, lattice topology, hybrid ladder lattice topology, or the like. An example ladder filter of BAW resonators with different ion implanted mass load doses will be described with reference to FIG. 21.

FIG. 21 is a schematic diagram of a ladder filter 210 that includes a plurality of BAW resonators 211 to 219. As illustrated, the ladder filter 210 includes series BAW resonators 211 to 215 and shunt BAW resonators 216 to 219. The BAW resonators 211 to 219 of the ladder filter 210 have 7 different resonant frequencies. The series resonators have 4 resonant frequencies: BAW resonators 211 and 212 have resonant frequency F1, BAW resonator 213 has resonant frequency F2, BAW resonator 214 has resonant frequency F3, and BAW resonator 215 has resonant frequency F4, where F1>F2>F3>F4. The shunt resonators have 3 resonant frequencies: BAW resonators 216 and 217 have resonant frequency F5, BAW resonator 218 has resonant frequency F6, and BAW resonator 219 has resonant frequency F7, where F5>F6>F7. F4 can be greater than F5. These example resonant frequency relationships can be for a band pass filter. For band pass filters, series resonators can provide an upper band edge of the frequency response and shunt resonators can provide a lower band edge of the frequency response. In contrast, for band rejection filters, series resonators can provide a lower band edge of the frequency response and shunt resonators can provide an upper band edge of the frequency response. The relative resonant frequency relationships discussed above for F1 to F7 can be modified accordingly when applied to a band rejection filter.

In some existing methods, forming resonators with 7 different resonant frequencies involves multiple processing iterations of depositing and/or etching material. As BAW stacks become thinner, mass load layers can also get thinner. It can be more challenging to reliably manufacture mass load layers with fine variations using existing deposition and/or etching techniques.

Methods disclosed herein can create BAW devices multiple resonant frequencies (e.g., resonant frequencies F1 to F7) where ion implantation varies mass loading between the BAW devices. One or more ion implanted mass loaded layers of different BAW resonators of the ladder filter 210 can be formed with different doping concentrations and/or dopants. This ion implantation can adjust mass loading of the BAW resonators and result in different respective resonant frequencies. Such a method can be performed to provide the BAW resonators of the ladder filter 210 with 7 different resonant frequencies F1 to F7.

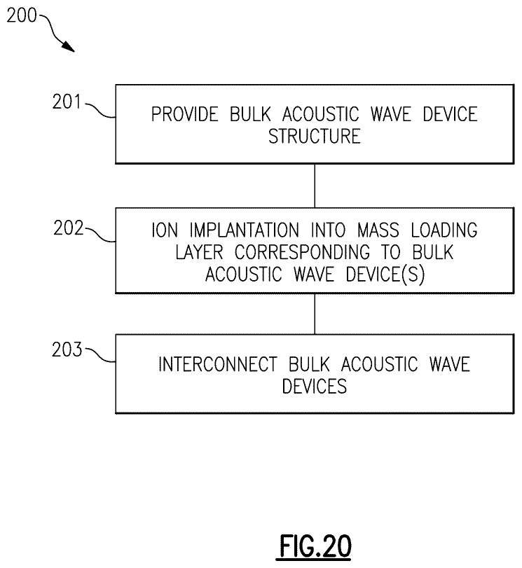

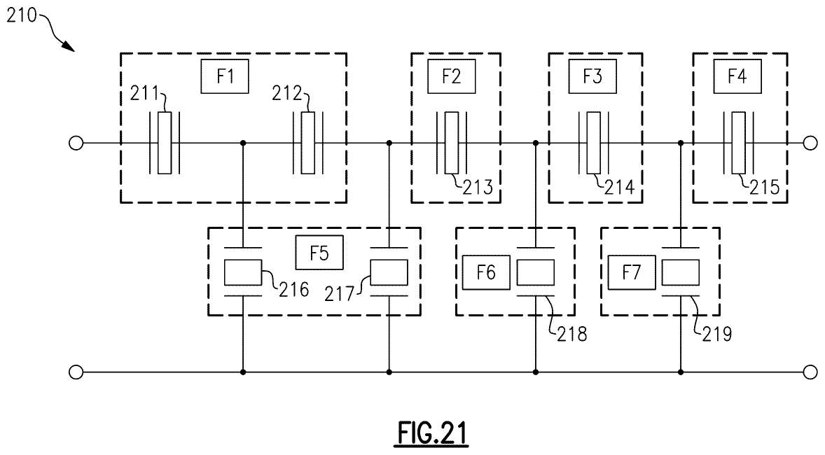

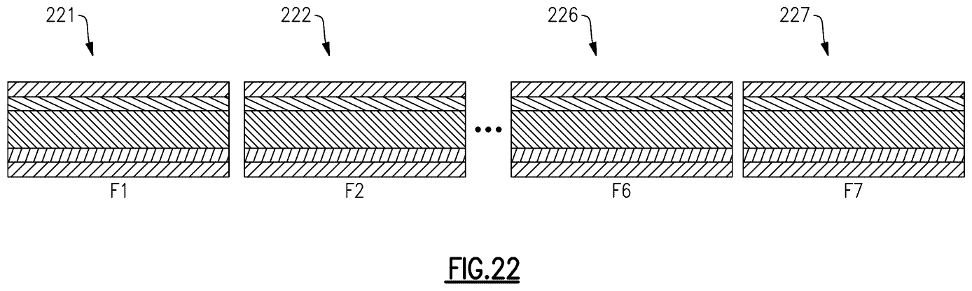

FIG. 22 is an example schematic cross-sectional diagram showing material stacks of example BAW resonators of the ladder filter 210 of FIG. 21 with different ion implanted mass load doses. The BAW resonator 221 has a resonant frequency of F1. The BAW resonator 221 does not include any ion implanted mass load dose and can thus provide a highest resonant frequency of the illustrated BAW resonators. The BAW resonator 221 can correspond to an example of BAW resonators 211 and 212 of FIG. 21. The BAW resonator 222 has a resonant frequency of F2. The BAW resonator 222 can have a mass loaded layer with an implanted species such that the mass loaded layer provides more mass loading than the corresponding layer in the BAW resonator 221. The BAW resonator 222 can correspond to an example of BAW resonator 213 of FIG. 21. The BAW resonator 226 has a resonant frequency of F6. The BAW resonator 226 can include an ion implanted mass loaded layer that provides more mass loading than the corresponding ion implanted mass loaded layer of the BAW resonator 222. Alternatively or additionally, the BAW resonator 226 can include an implanted species in one or more additional layers relative to the BAW resonator 222. In some instances, the BAW resonator 226 can include a mass loading that is thicker or that includes a thicker portion than the corresponding layer on the BAW resonator 222. The BAW resonator 226 can correspond to the of BAW resonator 218 of FIG. 21. The BAW resonator 227 has a resonant frequency of F7. The BAW resonator 227 can correspond to the BAW resonator 219 of FIG. 21. The BAW resonator 227 has a maximum mass loading of the BAW resonators of FIG. 22. The BAW resonator 227 can have a lowest resonant frequency of the illustrated BAW resonators due to having the greatest mass loading. BAW resonators with resonant frequencies of between F2 and F6 can be implemented with one or more ion implanted mass loaded layers that provide mass loading in between the mass loading of the BAW resonators 222 and 226.

Acoustic wave devices disclosed herein can be implemented as acoustic wave resonators in a variety of filters. Such filters can be arranged to filter a radio frequency signal. Acoustic wave devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 23A.

FIG. 23A is a schematic diagram of a ladder filter 230 that includes an acoustic wave resonator according to an embodiment. The ladder filter 230 is an example topology that can implement a band pass filter formed of acoustic wave resonators. In a band pass filter with a ladder filter topology, the shunt resonators can have lower resonant frequencies than the series resonators. The ladder filter 230 can be arranged to filter a radio frequency signal. As illustrated, the ladder filter 230 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, first input/output port I/O₁ can be a receive port and the second input/output port I/O₂ can be an antenna port. One or more of the acoustic wave resonators of the ladder filter 230 can include an acoustic wave device including a piezoelectric layer in accordance with any suitable principles and advantages disclosed herein. All acoustic resonators of the ladder filter 230 can include a piezoelectric layer in accordance with any suitable principles and advantages disclosed herein.

A filter that includes an acoustic wave resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5G NR specification. A filter that includes an acoustic wave resonator in accordance with any suitable principles and advantages disclosed herein can be arranged to filter a radio frequency signal in a fourth generation (4G) Long Term Evolution (LTE) operating band. A filter that includes an acoustic wave resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band.

The high acoustic velocity of piezoelectric layers disclosed herein can be advantageous for implementing BAW devices with relatively high resonant frequencies. This can be advantageous in acoustic wave filters for 5G applications. Yields of BAW resonators with relatively high resonant frequencies (e.g., resonant frequencies of at least 6 GHz) can be improved with piezoelectric layers disclosed herein. For example, BAW resonators with a resonant frequency of about 10 GHz can be achieved with piezoelectric layers disclosed herein at reasonable yields. The lower power density of piezoelectric layers disclosed herein compared to AlN piezoelectric layers can be advantageous in relatively high power applications, such as certain 5G applications. Strain in BAW devices can be reduced with piezoelectric layers disclosed herein.

FIG. 23B is schematic diagram of an acoustic wave filter 240. The acoustic wave filter 240 can include the acoustic wave resonators of the ladder filter 230. The acoustic wave filter 240 is a band pass filter. The acoustic wave filter 240 is arranged to filter a radio frequency signal. The acoustic wave filter 240 includes one or more acoustic wave devices coupled between a first input/output port RF_IN and a second input/output port RF_OUT. The acoustic wave filter 240 includes an acoustic wave resonator according to an embodiment.

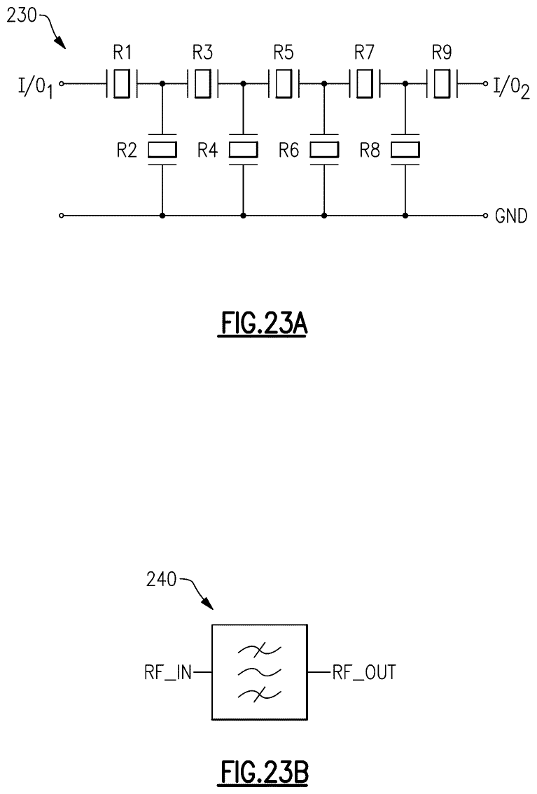

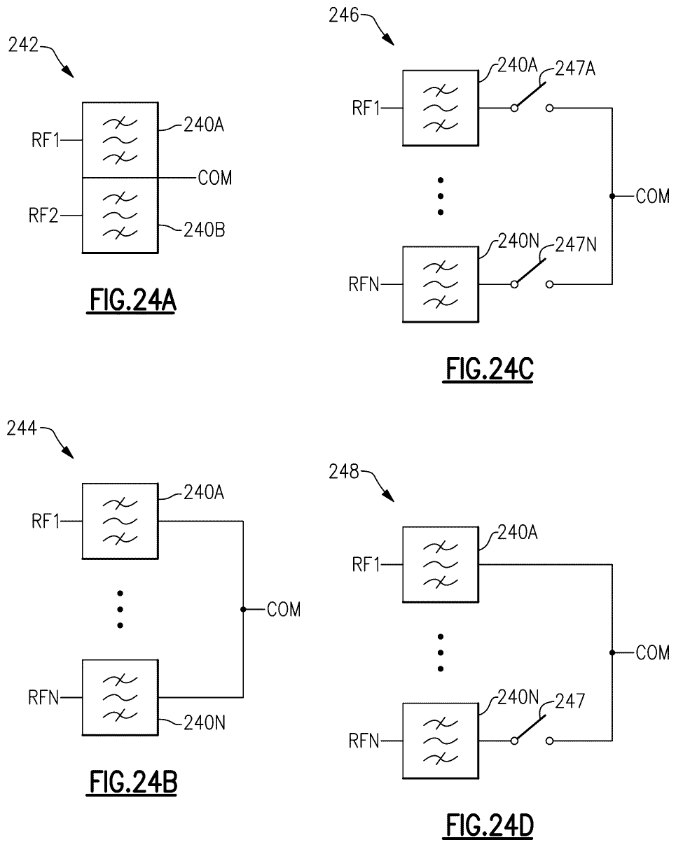

The acoustic wave device disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexer will be discussed with reference to FIGS. 24A to 24D. Any suitable principles and advantages of these multiplexers can be implemented together with each other.

FIG. 24A is a schematic diagram of a duplexer 242 that includes an acoustic wave filter according to an embodiment. The duplexer 242 includes a first filter 240A and a second filter 240B coupled together at a common node COM. One of the filters of the duplexer 242 can be a transmit filter and the other of the filters of the duplexer 242 can be a receive filter. In some other instances, such as in a diversity receive application, the duplexer 242 can include two receive filters. Alternatively, the duplexer 242 can include two transmit filters. The common node COM can be an antenna node.

The first filter 240A is an acoustic wave filter arranged to filter a radio frequency signal. The first filter 240A includes one or more acoustic wave resonators coupled between a first radio frequency node RF1 and the common node COM. The first radio frequency node RF1 can be a transmit node or a receive node. The first filter 240A includes an acoustic wave resonator in accordance with any suitable principles and advantages disclosed herein.

The second filter 240B can be any suitable filter arranged to filter a second radio frequency signal. The second filter 240B can be, for example, an acoustic wave filter, an acoustic wave filter that includes an acoustic wave resonator with a piezoelectric layer having a high acoustic velocity, an LC filter, a hybrid acoustic wave LC filter, or the like. The second filter 240B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 24B is a schematic diagram of a multiplexer 244 that includes an acoustic wave filter according to an embodiment. The multiplexer 244 includes a plurality of filters 240A to 240N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 240A to 240N each have a fixed electrical connection to the common node COM. This can be referred to as hard multiplexing or fixed multiplexing. Filters have fixed electrical connections to the common node in hard multiplexing applications.

The first filter 240A is an acoustic wave filter arranged to filter a radio frequency signal. The first filter 240A can include one or more acoustic wave devices coupled between a first radio frequency node RF1 and the common node COM. The first radio frequency node RF1 can be a transmit node or a receive node. The first filter 240A includes an acoustic wave resonator in accordance with any suitable principles and advantages disclosed herein. The other filter(s) of the multiplexer 244 can include one or more acoustic wave filters, one or more acoustic wave filters that include an acoustic wave resonator in accordance with any suitable principles and advantages disclosed herein, one or more LC filters, one or more hybrid acoustic wave LC filters, the like, or any suitable combination thereof.

FIG. 24C is a schematic diagram of a multiplexer 246 that includes an acoustic wave filter according to an embodiment. The multiplexer 246 is like the multiplexer 244 of FIG. 24B, except that the multiplexer 246 implements switched multiplexing. In switched multiplexing, a filter is coupled to a common node via a switch. In the multiplexer 246, the switches 247A to 247N can selectively electrically connect respective filters 240A to 240N to the common node COM. For example, the switch 247A can selectively electrically connect the first filter 240A the common node COM via the switch 247A. Any suitable number of the switches 247A to 247N can electrically a respective filter 240A to 240N to the common node COM in a given state. Similarly, any suitable number of the switches 247A to 247N can electrically isolate a respective filter 240A to 240N to the common node COM in a given state. The functionality of the switches 247A to 247N can support various carrier aggregations.

FIG. 24D is a schematic diagram of a multiplexer 248 that includes an acoustic wave filter according to an embodiment. The multiplexer 248 illustrates that a multiplexer can include any suitable combination of hard multiplexed and switched multiplexed filters. One or more acoustic wave devices in accordance with any suitable principles and advantages disclosed herein can be included in a filter (e.g., the filter 240A) that is hard multiplexed to the common node COM of the multiplexer 248. Alternatively or additionally, one or more acoustic wave devices in accordance with any suitable principles and advantages disclosed herein can be included in a filter (e.g., the filter 240N) that is switch multiplexed to the common node COM of the multiplexer 248.

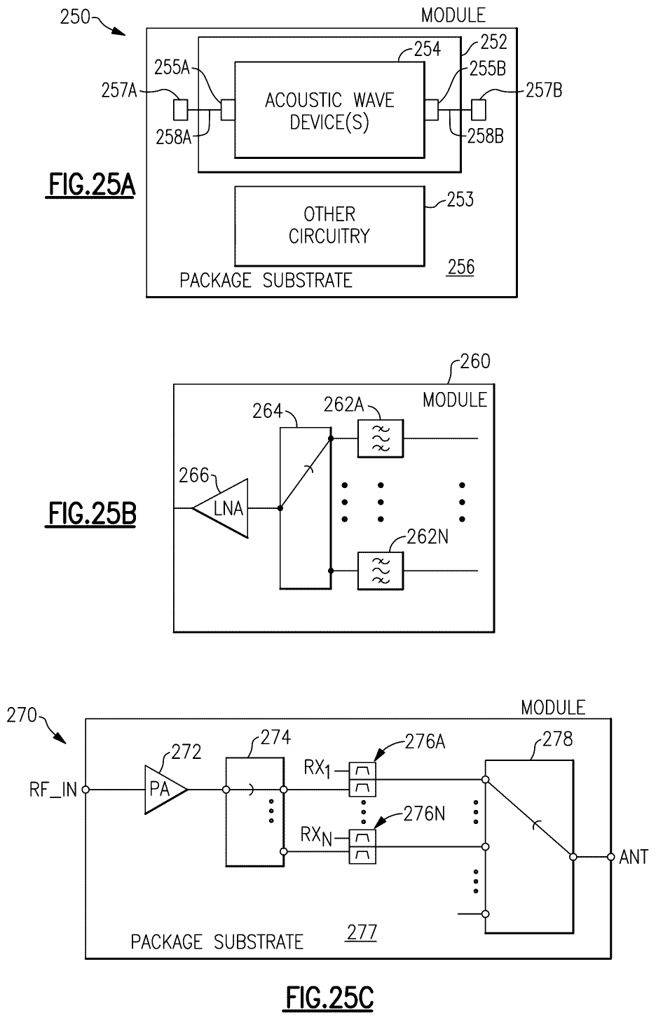

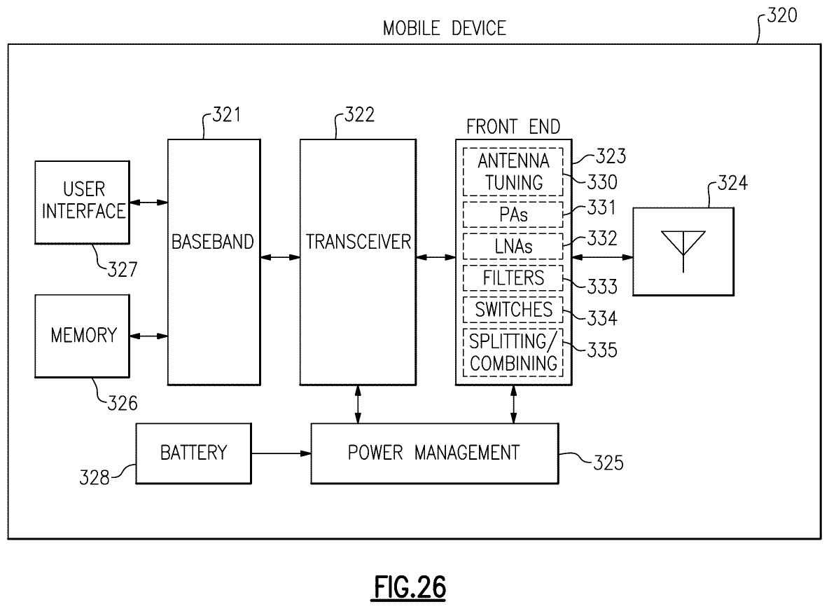

Acoustic wave devices disclosed herein can be implemented in a variety of packaged modules. Some example packaged modules will now be disclosed in which any suitable principles and advantages of the acoustic wave devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 25A to 25C are schematic block diagrams of illustrative packaged modules according to certain embodiments. Any suitable combination of features of these packaged modules can be implemented with each other.

FIG. 25A is a schematic diagram of a radio frequency module 250 that includes an acoustic wave component 252 according to an embodiment. The illustrated radio frequency module 250 includes the acoustic wave component 252 and other circuitry 253. The acoustic wave component 252 can include an acoustic wave filter that includes a plurality of acoustic wave devices, for example. The acoustic wave devices can be BAW devices in certain applications.

The acoustic wave component 252 shown in FIG. 25A includes one or more acoustic wave devices 254 and terminals 255A and 255B. The one or more acoustic wave devices 254 include at least one acoustic wave device implemented in accordance with any suitable principles and advantages disclosed herein. The terminals 255A and 254B can serve, for example, as an input contact and an output contact. Although two terminals are illustrated, any suitable number of terminals can be implemented for a particular application. The acoustic wave component 252 and the other circuitry 253 are on a common packaging substrate 256 in FIG. 25A. The packaging substrate 256 can be a laminate substrate. The terminals 255A and 255B can be electrically connected to contacts 257A and 257B, respectively, on the packaging substrate 256 by way of electrical connectors 258A and 258B, respectively. The electrical connectors 258A and 258B can be bumps or wire bonds, for example.

The other circuitry 253 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 253 can include one or more radio frequency circuit elements. The other circuitry 253 can be electrically connected to the one or more acoustic wave devices 254. The radio frequency module 170 can include one or more packaging structures to, for example, provide protection and/or facilitate easier handling of the radio frequency module 250. Such a packaging structure can include an overmold structure formed over the packaging substrate 256. The overmold structure can encapsulate some or all of the components of the radio frequency module 250.

FIG. 25B is a schematic block diagram of a module 260 that includes filters 262A to 262N, a radio frequency switch 264, and a low noise amplifier 266 according to an embodiment. One or more filters of the filters 262A to 262N can include any suitable number of bulk acoustic wave devices in accordance with any suitable principles and advantages disclosed herein. Any suitable number of filters 262A to 262N can be implemented. The illustrated filters 262A to 262N are receive filters. One or more of the filters 262A to 262N can be included in a multiplexer that also includes a transmit filter and/or another receive filter. The radio frequency switch 264 can be a multi-throw radio frequency switch. The radio frequency switch 264 can electrically couple an output of a selected filter of filters 262A to 262N to the low noise amplifier 266. In some embodiments, a plurality of low noise amplifiers can be implemented. The module 260 can include diversity receive features in certain applications.

FIG. 25C is a schematic diagram of a radio frequency module 270 that includes an acoustic wave filter according to an embodiment. As illustrated, the radio frequency module 270 includes duplexers 276A to 276N, a power amplifier 272, a radio frequency switch 274 configured as a select switch, and an antenna switch 278. The radio frequency module 270 can include a package that encloses the illustrated elements. The illustrated elements can be disposed on a common packaging substrate 277. The packaging substrate 277 can be a laminate substrate, for example. A radio frequency module that includes a power amplifier can be referred to as a power amplifier module. A radio frequency module can include a subset of the elements illustrated in FIG. 25C and/or additional elements. The radio frequency module 270 may include any one of the acoustic wave filters that include at least one bulk acoustic wave resonator in accordance with any suitable principles and advantages disclosed herein.

The duplexers 276A to 276N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include an acoustic wave device in accordance with any suitable principles and advantages disclosed herein. Similarly, one or more of the receive filters can include an acoustic wave device in accordance with any suitable principles and advantages disclosed herein. Although FIG. 25C illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 272 can amplify a radio frequency signal. The illustrated radio frequency switch 274 is a multi-throw radio frequency switch. The radio frequency switch 274 can electrically couple an output of the power amplifier 272 to a selected transmit filter of the transmit filters of the duplexers 276A to 276N. In some instances, the radio frequency switch 274 can electrically connect the output of the power amplifier 272 to more than one of the transmit filters. The antenna switch 278 can selectively couple a signal from one or more of the duplexers 276A to 276N to an antenna port ANT. The duplexers 276A to 276N can be associated with different frequency bands and/or different modes of operation (e.g., different power modes, different signaling modes, etc.).

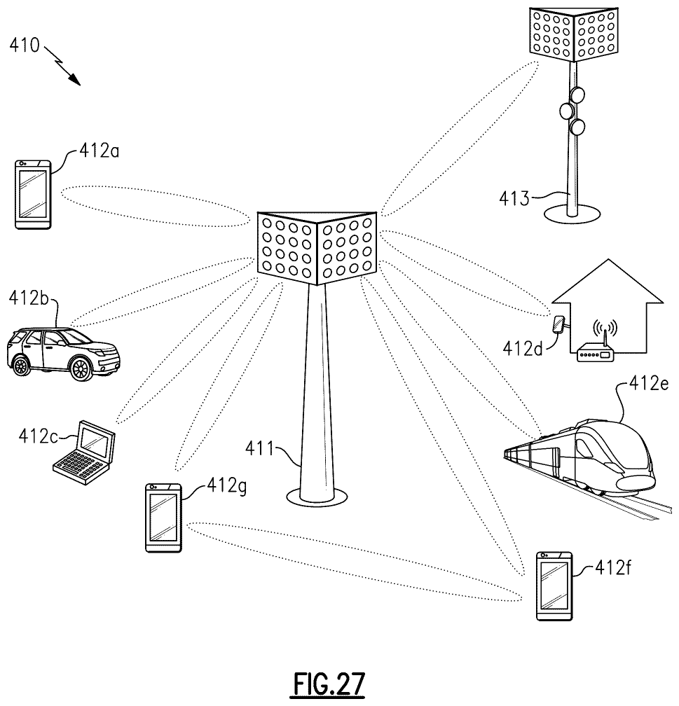

The acoustic wave devices disclosed herein can be implemented in wireless communication devices. FIG. 26 is a schematic block diagram of a wireless communication device 320 that includes an acoustic wave device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 26 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAS) 331, low noise amplifiers (LNAs) 332, filters 333, switches 334, and signal splitting/combining circuitry 335. However, other implementations are possible. The filters 333 can include one or more acoustic wave filters that include any suitable number of acoustic wave devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 26, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 26, the power management system 325 receives a battery voltage from the battery 328. The battery 328 can be any suitable battery for use in the wireless communication device 320, including, for example, a lithium-ion battery.

Technology disclosed herein can be implemented in acoustic wave filters in 5G applications. 5G technology is also referred to herein as 5G New Radio (NR). 5G NR supports and/or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR. An acoustic wave device including any suitable combination of features disclosed herein be included in a filter arranged to filter a radio frequency signal in a 5G NR operating band within Frequency Range 1 (FR1). A filter arranged to filter a radio frequency signal in a 5G NR operating band can include one or more BAW devices disclosed herein. FR1 can be from 410 MHz to 7.125 GHZ, for example, as specified in a current 5G NR specification. One or more BAW devices in accordance with any suitable principles and advantages disclosed herein can be included in a filter arranged to filter a radio frequency signal in a fourth generation (4G) Long Term Evolution (LTE). One or more BAW devices in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application.

BAW devices disclosed herein can provide high resonant frequencies and/or desirable power ruggedness. Such features can be advantageous in 5G NR applications. For example, such filters can filter RF signals within high frequency bands. At the same time, the filters can have desirable power ruggedness for meeting 5G performance specifications at the filter level and/or at the system level.

FIG. 27 is a schematic diagram of one example of a communication network 410. The communication network 410 includes a macro cell base station 411, a small cell base station 413, and various examples of user equipment (UE), including a first mobile device 412a, a wireless-connected car 412b, a laptop 412c, a stationary wireless device 412d, a wireless-connected train 412e, a second mobile device 412f, and a third mobile device 412g. UEs are wireless communication devices. One or more of the macro cell base station 411, the small cell base station 413, or UEs illustrated in FIG. 27 can implement one or more of the acoustic wave filters in accordance with any suitable principles and advantages disclosed herein. For example, one or more of the UEs shown in FIG. 27 can include one or more acoustic wave filters that include any suitable number of BAW resonators in accordance with any suitable principles and advantages disclosed herein.

Although specific examples of base stations and user equipment are illustrated in FIG. 27, a communication network can include base stations and user equipment of a wide variety of types and/or numbers. For instance, in the example shown, the communication network 410 includes the macro cell base station 411 and the small cell base station 413. The small cell base station 413 can operate with relatively lower power, shorter range, and/or with fewer concurrent users relative to the macro cell base station 411. The small cell base station 413 can also be referred to as a femtocell, a picocell, or a microcell. Although the communication network 410 is illustrated as including two base stations, the communication network 410 can be implemented to include more or fewer base stations and/or base stations of other types.

Although various examples of user equipment are shown, the teachings herein are applicable to a wide variety of user equipment, including, but not limited to, mobile phones, tablets, laptops, Internet of Things (IoT) devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 410 of FIG. 27 supports communications using a variety of cellular technologies, including, for example, 4G LTE and 5G NR. In certain implementations, the communication network 410 is further adapted to provide a wireless local area network (WLAN), such as WiFi. Although various examples of communication technologies have been provided, the communication network 410 can be adapted to support a wide variety of communication technologies.

Various communication links of the communication network 410 have been depicted in FIG. 27. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 27, the communication links include not only communication links between UE and base stations, but also UE to UE communications and base station to base station communications. For example, the communication network 410 can be implemented to support self-fronthaul and/or self-backhaul (for instance, as between mobile device 412g and mobile device 412f).

The communication links can operate over a wide variety of frequencies. In certain implementations, communications are supported using 5G NR technology over one or more frequency bands that are less than 6 GHz and/or over one or more frequency bands that are greater than 6 GHz. According to certain implementations, the communication links can serve Frequency Range 1 (FR1), Frequency Range 2 (FR2), or a combination thereof. An acoustic wave filter in accordance with any suitable principles and advantages disclosed herein can filter a radio frequency signal within FR1. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 410 can share available network resources, such as available frequency spectrum, in a wide variety of ways. In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 3 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 410 of FIG. 27 can be used to support a wide variety of advanced communication features, including, but not limited to, eMBB, uRLLC, and/or mMTC.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHZ, in FR1, in a frequency range from about 2 GHz to 10 GHz, in a frequency range from about 2 GHz to 15 GHz, or in a frequency range from 5 GHz to 20 GHz.

### Additional Examples I

1. A method of fabricating an acoustic wave device, the method comprising:
providing a piezoelectric layer for forming the acoustic wave device;
selectively implanting ions into localized regions of the piezoelectric layer; and
further processing to configure the acoustic wave device to generate an acoustic wave.

2. The method of Example 1, wherein selectively implanting the ions into the piezoelectric layer comprises locally modifying a piezoelectric material property.

3. The method of Example 2, wherein selectively implanting the ions comprises forming over the piezoelectric layer a patterning layer having openings therethrough, and implanting into the openings.

4. The method of Example 3, wherein the piezoelectric material property comprises a material-coupling coefficient (kₜ²).

5. The method of Example 4, wherein locally modifying the piezoelectric material property comprises locally reducing the kₜ².

6. The method of Example 3, wherein selectively implanting comprises locally reducing a crystallinity of the piezoelectric layer.

7. The method of Example 6, wherein selectively implanting comprises implanting noble gas ions.

8. The method of Example 3, wherein selectively implanting comprises implanting oxygen ions.

9. The method of Example 3, wherein selectively implanting comprises implanting hydrocarbon ions.

10. The method of Example 5, wherein providing the piezoelectric layer comprises depositing a material having a wurtzite crystal structure.

11. The method of Example 10, wherein the material comprises an AlN-based material.

12. The method of Example 11, wherein selectively implanting comprises implanting ions of one or more dopant elements selected from the group consisting of O, Ar, B, Si and C.

13. The method of Example 12, wherein selectively implanting comprises further implanting nitrogen ions.

14. The method of Example 5, wherein the acoustic wave device comprises an acoustic wave resonator and the localized regions comprise edge regions of an active area of the acoustic wave resonator.

15. The method of Example 5, further comprising forming a frame structure over the piezoelectric layer, wherein the localized regions at least partly overlap with the frame structure.

16. The method of Example 15, wherein the localized regions substantially entirely overlap with the frame structure.

17. A method of fabricating one or more acoustic wave devices, the method comprising:
providing a plurality of piezoelectric layers laterally arranged over a common substrate;
implanting different ones of the piezoelectric layers differently; and
further processing to form the one or more acoustic wave devices configured to generate an acoustic wave.

18. The method of Example 17, wherein implanting the different ones of the piezoelectric layers differently comprises sequentially exposing some of the piezoelectric layers and implanting into exposed ones of the piezoelectric layers while covering remaining ones of the piezoelectric layers.

19. The method of Example 18, wherein implanting ions into the plurality of piezoelectric layers comprises implanting same ions at different doses.

20. The method of Example 18, wherein implanting ions into the plurality of piezoelectric layers comprises implanting different ions.

21. The method of Example 18, wherein implanting the ions into the piezoelectric layer comprises modifying some of the of piezoelectric layers to have a different piezoelectric material property relative to others of the piezoelectric layers.

22. The method of Example 21, wherein the piezoelectric material property comprises a material-coupling coefficient (kₜ²).

23. The method of Example 22, wherein modifying some of the piezoelectric layers comprises increasing the kₜ² of the some of the piezoelectric layers relative to others of the piezoelectric layers.

24. The method of Example 23, wherein the piezoelectric layers comprise an AlN-based material.

25. The method of Example 24, wherein the implanted ions comprise ions of a dopant element selected from the group consisting of Cr, Sc, Y, Mg, Zr and Hf.

26. The method of Example 24, wherein the implanted ions further comprise nitrogen ions.

27. The method of Example 22, wherein modifying some of the piezoelectric layers comprises decreasing the kₜ² of some of the piezoelectric layers relative to others of the piezoelectric layers.

28. The method of Example 27, wherein the piezoelectric layers comprise an AlN-based material.

29. The method of Example 28, wherein the implanted ions comprise ions of a dopant element selected from the group consisting of O, Ar, B, Si and C.

30. The method of Example 29, wherein the implanted ions further comprise nitrogen ions.

31. A method of fabricating one or more acoustic wave devices, the method comprising:
providing a piezoelectric layer over a substrate;
blanket-implanting ions into the piezoelectric layer; and
patterning the piezoelectric layer and further processing to form the one or more acoustic wave devices configured to generate an acoustic wave.

32. The method of Example 31, wherein the implanted ions comprise ions of an element that is not present in the piezoelectric layer prior to blanket-implanting.

33. The method of Example 31, wherein the implanted ions comprise ions of an element that is present in the piezoelectric layer prior to blanket-implanting.

34. The method of Example 31, wherein providing the piezoelectric layer comprises providing the piezoelectric layer having a degree of composition nonuniformity with respect to an element prior to blanket-implanting, and wherein blanket-implanting comprises implanting the element to reduce the degree of the composition nonuniformity.

35. The method of Example 34, wherein blanket-implanting comprises implanting a higher dose of an element at one of a central region or an edge region of the piezoelectric layer relative to the other of the central region or the edge region.

36. The method of Example 35, wherein the one of the central region or the edge region has a lower concentration of the element relative the other of the central region or the edge region prior to blanket-implanting.

37. The method of Example 31, wherein blanket-implanting the ions into the piezoelectric layer comprises modifying a piezoelectric material property of a region of the piezoelectric layer at a higher magnitude relative to other regions of the piezoelectric layer.

38. The method of Example 37, wherein the piezoelectric material property comprises a material-coupling coefficient (kₜ²).

39. The method of Example 38, wherein modifying the piezoelectric material property comprises increasing the kₜ² of the region of the piezoelectric layer relative to the other regions of the piezoelectric layer.

40. The method of Example 39, wherein the piezoelectric layer comprises an AlN-based material.

41. The method of Example 40, wherein the blanket-implanted ions comprise one or more of Cr, Sc, Y, Mg, Zr and Hf.

42. The method of Example 38, wherein modifying the piezoelectric material property comprises increasing the kₜ² of the region of the piezoelectric layer relative to the other regions of the piezoelectric layer.

43. The method of Example 41, wherein the piezoelectric layer comprises an AlN-based material.

44. The method of Example 43, wherein the blanket-implanted ions comprise one or more of O, Ar, B, Si and C.

45. The method of Example 31, wherein the piezoelectric layer comprises a concentration gradient with respect to an element, and wherein blanket-implanting ions into the piezoelectric layer comprises at least partly reducing the concentration gradient.

### Additional Examples II

1. An acoustic wave device comprising:
a piezoelectric layer comprising localized regions having atoms implanted therein; and
an electrode over the piezoelectric layer, the acoustic wave device configured to generate an acoustic wave.

2. The acoustic device of Example 1, the localized regions have a locally modified piezoelectric material property.

3. The acoustic device of Example 2, wherein the locally modified piezoelectric material property comprises a material-coupling coefficient (kₜ²).

4. The acoustic device of Example 3, wherein the localized modified piezoelectric material property comprises the kₜ² that is locally lower relative to regions surrounding the localized regions.

5. The acoustic device of Example 3, wherein the localized regions comprise a degree of crystallinity that is lower relative to regions surrounding the localized regions.

6. The acoustic device of Example 5, wherein the localized regions comprise noble gas atoms implanted therein.

7. The acoustic device of Example 3, wherein the localized regions comprise higher oxygen content relative to regions surrounding the localized regions.

8. The acoustic device of Example 3, wherein the localized regions comprise hydrocarbon atoms implanted therein.

9. The acoustic device of Example 3, wherein the piezoelectric layer has a wurtzite crystal structure.

10. The acoustic device of Example 9, wherein the piezoelectric material comprises an AlN-based material.

11. The acoustic device of Example 9, wherein the localized regions comprise one or more of O, Ar, B, Si and C implanted therein.

12. The acoustic device of Example 9, wherein the localized regions comprise nitrogen atoms implanted therein.

13. The acoustic device of Example 9 wherein the acoustic wave device comprises an acoustic wave resonator and the localized regions comprise edge regions of an active area of the acoustic wave resonator.

14. The acoustic device of Example 4, further comprising a frame structure over the piezoelectric layer, wherein the localized regions at least partly overlap with the frame structure.

15. The acoustic device of Example 14, wherein the localized regions substantially entirely overlap with the frame structure.

16. An acoustic device comprising:
a plurality of piezoelectric layers laterally arranged over a common substrate, different ones of the piezoelectric layers being implanted differently; and
electrodes formed over the piezoelectric layers and configured to generate an acoustic wave.

17. The acoustic device of Example 16, wherein different ones of the piezoelectric layers have implanted therein the same atom implanted at the different doses.

18. The acoustic device of Example 16, wherein different ones of the piezoelectric layers have implanted therein different atoms implanted.

19. The acoustic device of Example 16, wherein the different ones of the piezoelectric layers have a different piezoelectric material property relative to each other.

20. The acoustic device of Example 19, wherein the different piezoelectric material property comprises a material-coupling coefficient (kₜ²).

21. The acoustic device of Example 20, wherein the piezoelectric layers comprise an AlN-based material, and wherein higher implantation dose correlates to higher kₜ².

22. The acoustic device of Example 21, wherein the implanted atoms include an element selected from the group consisting of Cr, Sc, Y, Mg, Zr and Hf.

23. The acoustic device of Example 22, wherein the implanted atoms further include nitrogen atoms.

24. The acoustic device of Example 20, wherein the piezoelectric layers comprise an AlN-based material, and wherein higher implantation dose correlates to lower kₜ².

25. The acoustic device of Example 24, wherein the implanted atoms include an element selected from the group consisting of O, Ar, B, Si and C.

26. The acoustic device of Example 25, wherein the implanted atoms further include nitrogen atoms.

### Additional Examples III

1. An acoustic wave device with temperature compensation, the acoustic wave device comprising:
a piezoelectric layer;
an electrode; and
a temperature compensation layer including an implanted species therein from ion implantation, the acoustic wave device configured to generate an acoustic wave.

1. The acoustic wave device of Example 1 wherein the temperature compensation layer is in physical contact with the piezoelectric layer.

2. The acoustic wave device of Example 1 wherein the acoustic wave device is a bulk acoustic wave device, and the acoustic wave is a bulk acoustic wave.

3. The acoustic wave device of Example 3 wherein the temperature compensation layer is positioned between the piezoelectric layer and the electrode.

4. The acoustic wave device of Example 3 wherein the temperature compensation layer is embedded in the electrode.

5. The acoustic wave device of Example 1 wherein the temperature compensation layer includes silicon dioxide.

6. The acoustic wave device of Example 1 wherein the implanted species comprises at least one of boron or phosphorous.

7. The acoustic wave device of Example 1 wherein the implanted species comprises at least one of boron, phosphorus, tellurium, titanium, germanium, fluorine or carbon.

8. The acoustic wave device of Example 1 wherein the implanted species has a concentration of 20% or less in the temperature compensation layer.

9. The acoustic wave device of Example 1 wherein the implanted species has a concentration of 2% or less in the temperature compensation layer.

10. A method of manufacturing an acoustic wave device with temperature compensation, the method comprising:
providing an acoustic wave device structure that includes a temperature compensation layer;
performing ion implantation to implant a dopant in the temperature compensation layer.

11. The method of Example 11 wherein the acoustic wave device is a bulk acoustic wave device.

12. The method of Example 11 wherein the acoustic wave device structure includes a piezoelectric layer in physical contact with the temperature compensation layer.

13. The method of Example 13 further comprising forming an electrode over the temperature compensation layer such that the temperature compensation layer is positioned between the piezoelectric layer and the electrode.

14. The method of Example 11 wherein the acoustic wave device structure includes at least a portion of an electrode, and the temperature compensation layer is embedded in the electrode after the method is performed.

15. The method of Example 11 wherein the acoustic wave device structure includes an electrode layer, and the temperature compensation layer is over the electrode layer.

16. The method of Example 16 further comprising forming a piezoelectric layer over the temperature compensation layer such that the temperature compensation layer is positioned between the electrode layer and the piezoelectric layer.

17. The method of Example 11 wherein the temperature compensation layer includes silicon dioxide.

18. The method of Example 11 wherein the dopant includes at least one of boron or phosphorus.

19. The method of Example 11 wherein the dopant includes at least one of boron, phosphorus, tellurium, titanium, germanium, fluorine or carbon.

20. The method of Example 11 wherein a concentration of the dopant in the temperature compensation layer is less than 20%.

21. The method of Example 11 wherein a concentration of the dopant in the temperature compensation layer is less than 2%.

22. An acoustic wave filter comprising:
an acoustic wave device of any preceding Example; and
a plurality of additional acoustic wave devices, the acoustic wave filter configured to filter a radio frequency signal.

23. A radio frequency module comprising:
an acoustic wave filter including an acoustic wave device of any preceding Example; and
a radio frequency circuit element coupled to the acoustic wave filter, the acoustic wave filter and the radio frequency circuit element being enclosed within a common package.

24. A wireless communication device comprising:
an acoustic wave filter including an acoustic wave device of any preceding Example;
an antenna operatively coupled to the acoustic wave filter;
a radio frequency amplifier operatively coupled to the acoustic wave filter and configured to amplify a radio frequency signal; and
a transceiver in communication with the radio frequency amplifier.

25. A method of filtering a radio frequency signal, the method comprising:
receiving a radio frequency signal at a port of an acoustic wave filter that includes an acoustic wave device of any preceding Example; and
filtering the radio frequency signal with the acoustic wave filter.

### Additional Examples IV

1. An acoustic wave component with mass loaded bulk acoustic wave devices, the acoustic wave component comprising:
a first bulk acoustic wave device having a first resonant frequency; and
a second bulk acoustic wave device having a second resonant frequency, the second bulk wave device including a mass loaded layer having an implanted species therein from ion implantation, the implanted species of the mass loaded layer contributing to a difference between the first resonant frequency and the second resonant frequency.

2. The acoustic wave component of Example 1 wherein an electrode of the second bulk acoustic wave device includes the mass loaded layer.

3. The acoustic wave component of Example 1 wherein a passivation layer of the second bulk acoustic wave device includes the mass loaded layer.

4. The acoustic wave component of Example 1 wherein the first bulk acoustic wave device and the second bulk acoustic wave device are included in the same filter.

5. The acoustic wave component of Example 1 wherein the first bulk acoustic wave device and the second bulk acoustic wave device are on a same die.

6. The acoustic wave component of Example 1 wherein the implanted species includes at least one of iridium, osmium, platinum, chromium, tungsten, ruthenium, or molybdenum.

7. The acoustic wave component of Example 1 wherein second bulk acoustic wave device includes a second mass loaded layer having a second implanted species therein from ion implantation, the second mass loaded layer contributing to the difference between the first resonant frequency and the second resonant frequency.

8. A method of manufacturing bulk acoustic wave devices with mass loading using ion implantation, the method comprising:
providing a bulk acoustic wave device structure that includes a first layer in a first area corresponding to a first bulk acoustic wave device and a second layer in a second area corresponding to a second bulk acoustic wave device; and
performing ion implantation to implant a dopant into the first layer such that the first layer has a greater mass than the second layer.

9. The method of Example 8 wherein an electrode of the first bulk acoustic wave device includes the first layer.

10. The method of Example 8 wherein the dopant includes a different material than the first layer.

11. The method of Example 8 wherein the dopant includes a same material than the first layer.

12. The method of Example 8 wherein a passivation layer of the first bulk acoustic wave device includes the first layer.

13. The method of Example 8 wherein the dopant includes at least one of iridium, osmium, platinum, chromium, tungsten, ruthenium, or molybdenum.

14. The method of Example 8 further comprising connecting the first bulk acoustic wave device and the second bulk acoustic wave device such that the first bulk acoustic wave device and the second acoustic wave device are in a single filter.

15. The method of Example 8 wherein the performing ion implantation also introduces the dopant into a third layer in a third area of the bulk acoustic wave device structure corresponding to a third bulk acoustic wave device.

16. An acoustic wave filter comprising:
an acoustic wave device of any preceding Example; and
a plurality of additional acoustic wave devices, the acoustic wave filter configured to filter a radio frequency signal.

17. A radio frequency module comprising:
an acoustic wave filter including an acoustic wave device of any preceding Example; and
a radio frequency circuit element coupled to the acoustic wave filter, the acoustic wave filter and the radio frequency circuit element being enclosed within a common package.

18. A wireless communication device comprising:
an acoustic wave filter including an acoustic wave device of any preceding Example;
an antenna operatively coupled to the acoustic wave filter;
a radio frequency amplifier operatively coupled to the acoustic wave filter and configured to amplify a radio frequency signal; and
a transceiver in communication with the radio frequency amplifier.

19. A method of filtering a radio frequency signal, the method comprising:
receiving a radio frequency signal at a port of an acoustic wave filter that includes an acoustic wave device of any preceding Example; and
filtering the radio frequency signal with the acoustic wave filter.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. An acoustic wave device comprising:
a piezoelectric layer comprising localized regions having atoms implanted therein; and
an electrode over the piezoelectric layer, the acoustic wave device configured to generate an acoustic wave.

2. The acoustic device of claim 1, the localized regions have a locally modified piezoelectric material property.

3. The acoustic device of claim 2, wherein the locally modified piezoelectric material property comprises a material-coupling coefficient (kₜ²).

4. The acoustic device of claim 3, wherein the localized modified piezoelectric material property comprises the kₜ² that is locally lower relative to regions surrounding the localized regions.

5. The acoustic device of claim 3, wherein the localized regions comprise a degree of crystallinity that is lower relative to regions surrounding the localized regions.

6. The acoustic device of claim 5, wherein the localized regions comprise noble gas atoms implanted therein.

7. The acoustic device of claim 3, wherein the localized regions comprise higher oxygen content relative to regions surrounding the localized regions.

8. The acoustic device of claim 3, wherein the localized regions comprise hydrocarbon atoms implanted therein.

9. The acoustic device of claim 3, wherein the piezoelectric layer has a wurtzite crystal structure.

10. The acoustic device of claim 9, wherein the piezoelectric material comprises an AlN-based material.

11. The acoustic device of claim 9, wherein the localized regions comprise one or more of O, Ar, B, Si and C implanted therein.

12. The acoustic device of claim 9, wherein the localized regions comprise nitrogen atoms implanted therein.

13. An acoustic device comprising:
a plurality of piezoelectric layers laterally arranged over a common substrate, different ones of the piezoelectric layers being implanted differently; and
electrodes formed over the piezoelectric layers and configured to generate an acoustic wave.

14. The acoustic device of claim 13, wherein different ones of the piezoelectric layers have implanted therein the same atom implanted at the different doses.

15. The acoustic device of claim 13, wherein different ones of the piezoelectric layers have implanted therein different atoms implanted.

16. The acoustic device of claim 13, wherein the different ones of the piezoelectric layers have a different piezoelectric material property relative to each other.

17. The acoustic device of claim 16, wherein the different piezoelectric material property comprises a material-coupling coefficient (kₜ²).

18. The acoustic device of claim 17, wherein the piezoelectric layers comprise an AlN-based material, and wherein higher implantation dose correlates to higher kₜ².

19. The acoustic device of claim 18, wherein the implanted atoms include an element selected from the group consisting of Cr, Sc, Y, Mg, Zr and Hf.

20. The acoustic device of claim 19, wherein the implanted atoms further include nitrogen atoms.
